(19) United States
(12) Patent Application Publication
(10) Pub. No.: US 2010/0154855 A1
(43) Pub. Date: Jun. 24, 2010

(54) Thin walled thermoelectric devices and methods for production thereof

(76) Inventors: David Nemir, El Paso, TX (US); Edward Rubia, Santa Teresa, NM (US); Jan Bastian Beck, El Paso, TX (US)

Correspondence Address: David C. Nemir, P.O. Box 23189, El Paso, TX, 79923-3189, US

(21) Appl. No.: 12/653,721

(22) Filed: Dec. 17, 2009

Related U.S. Application Data
(60) Provisional application No. 61/138,574, filed on Dec. 18, 2008.

(51) Int. Cl. H01L 35/30; H01L 35/34

(52) U.S. Cl. 136/205; 438/54

(57) ABSTRACT

A thermoelectric generator is built into the wall of a heat exchanger by applying coatings of dielectric, electrical conductor and N-type and P-type thermoelectric materials. A tubular heat exchanger lends itself to the application of coatings in annular rings, providing ease of manufacture and a structure that is robust to damage.

### REFERENCE TO PRIOR PROVISIONAL APPLICATION

This application claims the benefit of the filing date of prior filed U.S. Provisional Patent Application No. 61/138,574 filed Dec. 18, 2008, which is incorporated herein by reference as if written herein in its entirety.

### BACKGROUND OF THE INVENTION

1. Field of the Invention

This invention relates to thermoelectric devices and methods for building such devices into the walls of heat exchangers.

2. Background of the Invention

Thermoelectric phenomena arise out of the intercoupled electrical and thermal currents in a material. A thermoelectric generator may be viewed as a mechanism for energy conversion, transforming energy in one form (heat) into another form (electricity). The reason that this is often desirable is that electricity is a more versatile power source than heat. Electrical energy has the attractive property that it may be easily transmitted to remote locations via electrical conductors, without the requirement for mechanical transport. Electrical energy may be used for heating, lighting, the generation of mechanical motion through motors and actuators, or to power sensors and electronics.

The key component of a thermoelectric device is the thermoelement, which is the active portion that does the actual conversion. Although thermoelements may be built using conductors such as bismuth and antimony, higher efficiency thermoelectrics are built using heavily doped semiconductors. Thermoelectric devices are generally formed by connecting a number of n and p type thermoelements in electrical series and in thermal parallel. In n type thermoelements, the majority charge carriers are electrons. In p type elements, the majority charge carriers are holes.

Thermoelectric generation takes place when a temperature difference is applied to the thermoelements, causing mobile charge carriers, either electrons or holes, to migrate from hot to cold. The resulting separation of charge creates an electric potential known as the Seebeck voltage, that is given by ΔV=SΔT, where S is a temperature dependent material property known as the Seebeck coefficient or thermopower, and, by convention, ΔT represents the temperature of the cold side with respect to the hot side. The Seebeck coefficient for a material may be positive or negative depending upon the type of majority charge carrier.

Besides the thermopower, two other material parameters of interest when analyzing a thermoelectric material are the electrical conductivity, λ, and the thermal conductivity, λ, and are important when analyzing losses in a thermoelectric device. Losses due to Joule (I²R) heating within the active thermoelectric element are minimized when the thermoelements have a high electrical conductivity. Diffusive heat losses, due to thermal energy that passes all the way through the thermoelectric element without being converted to electricity, can be minimized by having a low thermal conductivity. In particular, the thermal conductivity may be reduced through techniques directed at inhibiting the propagation of quanta of lattice vibration which are also known as phonons.

The three key material properties governing thermoelectric performance are often lumped into a single thermoelectric figure of merit Z, where

$$Z = \frac{σ {S}^{2}}{λ} . \qquad ( 1 )$$

The parameters σ, S, and λ are temperature dependent and so Z is a function of temperature. In any thermoelectric element of uniform cross-section, A, and length, l, the electrical resistance, R_{E}, and thermal resistance, R_{T}, between the hot side and the cold side may be calculated respectively as

$$\begin{matrix}{R}_{E} = \frac{l}{σ A} \\ and & ( 2 ) \\ {R}_{T} = \frac{l}{λ A} & ( 3 )\end{matrix}$$

Using equations (1-3), it is straightforward to obtain an alternative expression for the thermoelectric figure of merit for a thermoelement of uniform composition, cross-sectional area and length:

$$Z = \frac{{S}^{2} {R}_{T}}{{R}_{E}} . \qquad ( 4 )$$

Higher values of Z give higher thermoelectric conversion efficiencies. However, for practical devices, the amount of power that can be generated from a given hot and cold reservoir will also depend upon the ability of the hot/cold reservoirs to deliver/absorb thermal energy to/from the thermoelectric generator. In particular, there may be a number of thermal interfaces separating the two reservoirs from the active thermoelectric material. These result in thermal contact resistances, across which there may be significant temperature drops, leading to a diminished thermal gradient across the thermoelement and thus reduced power generating capability.

The identification of Z as a figure of merit for thermoelectric materials originally arose out of a derivation for thermoelectric efficiency—the percentage of electrical energy that can be obtained by a device from a given amount of thermal energy. See for example, Ioffe, A. F., Semiconductor Thermoelements and Thermoelectric Cooling, London, Infosearch Ltd., 1957. Subject to certain assumptions, the maximum efficiency will always increase with increasing Z according to the formula:

$${η}_{max} = \frac{Δ T}{{T}_{h}} \times \frac{\sqrt{1 + ZT} - 1}{\sqrt{1 + ZT} + \frac{{T}_{c}}{{T}_{h}}} \qquad ( 5 )$$

where ηₘₐₓ is the maximum efficiency, Tₕ is the hot side temperature, is the cold side temperature and ΔT=Tₕ−T_{c}. Of particular note is the first term on the right in equation (5), which is an expression for the Carnot limit, the maximum theoretical efficiency with which thermal energy can be converted to work. Also of note is that Z is the only material and geometry dependent term in the calculation for thermoelectric efficiency. All of the information related to the number, material, size and shape of the thermoelements is embodied in Z. For thermoelements that are constructed from a state-of-the-art material like doped alloys of bismuth-telluride, with a Z of approximately 0.0029° K⁻¹, and a temperature across the thermoelectric of 400° K (hot side) to 300° K (cold side), the maximum efficiency by equation (5) is approximately 4.8%.

Conversion efficiency is not necessarily the most important criterion for a power generator, an idea that is illustrated by consideration of a resistive load attached to a Thevenin source model consisting of an ideal voltage source in series with a source resistance. A well known circuit theory result is that the maximum power transfer to the load occurs when the load resistance has the same value as the source resistance and corresponds to a power transfer efficiency of 50%. The efficiency increases as the load resistance is increased, but the amount of power transfer is reduced. For very high load resistances, the power transfer tends to zero but with an efficiency approaching 100%.

Consider a thermoelectric generator having an arbitrary number, j, of thermoelements, of uniform length, l, and cross-sectional area, A, half of which are N-type and half of which are P-type. Assume that all elements have a constant, temperature invariant, thermal conductivity, λ, electrical conductivity, σ, and thermopower magnitude, S, where we note that the thermopower for N-type material is negative and for P-type material is positive. Then assuming negligible resistance in the conductors that connect the thermoelements, the internal (source) electrical resistance and generated (open circuit) voltage of the thermoelectric generator are, respectively,

$$r = \frac{j l}{σ A} , {V}_{OC} = j S Δ T . \qquad ( 6 )$$

In order to obtain maximum power transfer from the thermoelectric generator to a resistive load R, we choose that load as R=r. Since it is possible to use an electrical converter which matches source and load impedances, this is a reasonable assumption. Then, by making use of equation (6), the output power is found to be,

$$W = \frac{{W}_{OC}^{2}}{4 r} = Δ {T}^{2} \times \frac{j A}{4 l} \times σ {S}^{2} . \qquad ( 7 )$$

See for example, D. Nemir and J. Beck, “On the significance of Z”, Proc. 12^{th} International Conference on Thermoelectrics, Freiberg, Germany, July 2009. The rightmost side of equation (7) provides a roadmap for maximizing generated power in a thermoelectric device. The first term in the product expresses the dependence upon the temperature difference, which has to do with the operating environment. Clearly, having high temperature differences is important and has a quadratic influence.

The second term in the product expresses the dependence of the power output upon the physical construction of the device, namely, the number of elements, cross-sectional area per element and length of the element (j, A and l respectively). This is an interesting result since it suggests that power generation can be increased not only by increasing the total area, jA, which is intuitive, but also by decreasing the element thickness, l, which is less obvious.

The third term expresses the influence of the material properties of the thermoelectric material, namely the product, σS², which is aptly named the “power factor”. The thermal conductivity, λ, does not explicitly appear in equation (7) but impacts generated power through its influence on the ΔT term when there are thermal resistances between the thermoelements and the thermal reservoirs.

All known thermoelectric materials have a temperature “sweet spot” where they yield optimal performance. In order to produce power, a thermoelectric generator must have a temperature gradient through the material. This means that at different distances from the hot side, there will be different temperatures within the thermoelectric material. In applications where there is a large temperature difference between the hot and cold sides of the generator, segmented thermoelements can be used that are made of two or more distinct thermoelectric materials, each chosen to be optimal over the temperature range that is expected in that region within the overall thermoelement. Alternatively, graded thermoelements can be used that are blended between two different thermoelectric materials with the percentage makeup changing in accordance with the distance from one end of the thermoelement.

For any given thermoelectric device that is operated within its design temperature, by equation (7), the generated power increases at a rate proportional to the square of the temperature across the device, ΔT². So having and maintaining a high ΔT is critical for maximum power generation. Removing heat from the cold side of the thermoelectric elements (to maintain a given T_{c}) is as important to maintaining ΔT as heat delivery to the hot side. Perhaps the best deployment of a thermoelectric generator is when it serves as the heat energy transfer medium between two fluids having a different temperature. Fluids are important because they serve as a heat delivery/removal means that includes conductive and convective heat transfer. Devices that are designed for heat transfer between fluids are known as heat exchangers. So, it is desirable to implement thermoelectric generation as part of the wall of a heat exchanger.

Heat exchangers are ubiquitous in power generation and industrial plants and are designed for the optimal transfer of heat energy into one side and out of the other side. Some examples are boilers (where the heat from combustion gases on one side is transferred to the other side to boil water or to heat steam) and recuperators, which use exhaust heat (hot side) to preheat incoming combustion air (cold side). Other types of heat exchangers are condensers and ventilated radiators. By deploying thermoelectric technology in the wall of a heat exchanger, disposed between the hot and the cold sides, it is possible to have electric generation occurring as a byproduct of heat exchange. In a heat exchanger, electricity that is thermoelectrically generated from heat energy passing through the heat exchanger wall is bonus electricity that goes straight to the bottom line. This is an important point and is best illustrated with an example. As the control, consider a boiler that is used in a conventional steam generation plant having an overall efficiency of 30%. In other words, for every kilowatt of heat energy flux that is generated from combusted fuel, 300 watts of electrical power is produced. In contrast, suppose that a thermoelectric generator with a 5% conversion efficiency is deployed in the wall of the boiler. In the second case, for every kilowatt of heat energy flux generated on the combustion side, 50 watts of electrical energy is generated from the thermoelectrics as the heat energy passes through the thermoelectrics and the remaining 950 watts passes through the heat exchanger wall into the boiler to create or heat steam, where it eventually generates 285 watts of electrical power (30% times 950 watts). So for the second case, the total electrical power that is generated per kilowatt of input heat energy flux is 335 watts. This is a 12% overall efficiency improvement.

3. Description of the Related Art

Thermoelectric generation as a way to generate electricity from fluids having different temperatures has been addressed by placing a thermoelectric generation module between channels containing the hot fluid and the cold fluid. See for example, K. Matsuura and D. Rowe, “Low temperature heat conversion”, in CRC Handbook of Thermoelectrics, D. M. Rowe, editor, CRC Press, Boca Raton, Fla., 1995, pp 573-593.

U.S. Pat. No. 6,127,766 (Roidt) describes a paired tube bank where a first tube element is constructed using an N-type of thermoelectric material applied to an inner conductive tube and then covered by an outer conductive tube, and a separate second tube element is constructed in a similar way using P-type thermoelectric material. Pairs of N-type and P-type tubes are exposed to hot gases and have a center coolant channel. A problem with this design is that since even the best thermoelectric materials have a Seebeck coefficient of only about 200 μV/° C., it requires the series electrical connection of many tubes to obtain an appreciable voltage level. Furthermore, the use of nested tubes adds thermal resistance between steam and chilling water, compromising the heat exchange function U.S. Pat. No. 6,367,261 B1 (Marshall et al) describes a thermoelectric power generator using a steam source and one or more thermoelectric modules embedded between nested condenser tubes. The invention does not address the requirement to minimize thermal resistance drops between hot and cold reservoirs, and the use of nested tubes adds thermal resistance between steam and chilling water, compromising the heat exchange function. U.S. Pat. No. 7,100,369 B2 (Yamaguchi et al) discloses exhaust heat recovery systems that process automotive exhaust heat to generate electricity, reducing the requirement of an electrical alternator to provide electrical power. The heat sink for the thermoelectric module is provided by using an engine coolant loop. This is an example of an application for thermoelectric generation that requires special modification, in this case, establishing the cool side for the thermoelectric. In contrast, the present invention can be applied to applications that are already served by a heat exchanger, already providing hot and cold sides for thermoelectric generation, and serving as a natural home for thermoelectric generation.

In order to generate usable voltages through thermoelectric means, it is necessary to connect many couples in electrical series, a process which can be laborious and can lead to problems at the interfaces and interconnections. This is a problem shared by status quo approaches to the design of thermoelectric generators for large scale power production. The present invention is based upon the use of coatings applied to the structural walls of heat exchangers to produce thermoelectric generators with improved performance.

Thermoelectric films have been reported for use in constructing thin film sensors and actuators. See for example, K. Matsubara, T. Koyanagi, N. Nagao and K. Kishimoto, “Preparation of thermoelectric films”, in CRC Handbook of Thermoelectrics, D. M. Rowe, editor, CRC Press, Boca Raton, Fla., 1995, pp 131-141. In these applications, techniques including sputtering, ion beam deposition, molecular beam epitathy and activated evaporation to deposit very thin layers of conductor, dielectric and thermoelectric material in order to build thin film devices with layers typically less than 1 μm thick. These techniques are expensive manufacturing approaches when considered on a square meter of thermoelectric generator surface. Furthermore, these techniques are not well suited for the volume production of devices having more than 1 μm in thickness.

When building a thermoelectric generator with coatings, there are three general classes of materials: dielectric, conductor and thermoelectric. Coatings may be added to a structure, or may be selectively removed. A category of application processes generically known as spraycasting represent an excellent approach for volume application of relatively thick films of greater than 20 μm. These techniques represent a variety of commercial technologies that go by a variety of names such as plasma spray, high velocity oxy-fuel, detonation spray, cold spray, impact consolidation and others. Each method accelerates a powdered material to a high velocity and possibly elevated temperature and impacts it onto a solid substrate. The distinction between the different approaches lie primarily in the velocity and temperatures. Some techniques (eg: high velocity oxy-fuel) can result in the presence of oxygen and hydrocarbons in the powder which may alter the properties of the deposited materials.

Typically, spray techniques are used to either deposit a wear resistant layer on top of a structural material or replace material that has been worn off already. In both cases the aim of the method is to obtain a good mechanical contact between substrate and the deposit. A side effect of this intimate mechanical contact is an intimate thermal contact, something that is quite desirable for a thermoelectric device.

The present invention is for high performance thermoelectric devices constructed by applying layers of conductor, dielectric and thermoelectric material directly to the wall of a heat exchanger or tube. In contrast to prior art approaches that are difficult to produce and limited in their deployment options, the present invention has the following advantages and benefits:

a) a thermoelectric generator can be built onto the wall of an existing heat exchanger design;
b) contact interfaces between thermoelectric material, conductors, insulators and support structure are reduced or eliminated, allowing for enhanced generating efficiencies;
c) the manufacturing technique is conducive to high volume production;
d) it allows the application of controlled coatings of thermoelectric material, conserving material and enhancing power generation;
e) in one preferred embodiment, a thermoelectric generator may be built from a single generic tube, with different tube lengths chosen for specific voltages;
f) in a tube embodiment of the thermoelectric generator is readily deployable as a pipe in a thermally conducting medium;
g) a tube embodiment of the thermoelectric generator lends itself to an volume manufacturing process; and
h) in a tube embodiment, the thermoelectric generator is very robust because the annular rings of dielectric, conductor and thermoelectric material are not easily disrupted by scratches and breaches and other damage.

Other objects and advantages will be apparent from the detailed drawings and description to follow.

### SUMMARY OF THE INVENTION

The present invention is for an apparatus and method of production of a thermoelectric device. The ability to add a thermoelectric generation capability by applying it in a coating to the surface of a conventional heat exchanger opens the doors to a myriad of possible applications in power plants, refineries and other applications. By selectively applying layers of dielectric, electrical conductor and N and P type thermoelectric material onto a heat exchanger wall, a thermoelectric generation capability can be added to a heat exchanger, allowing it to serve a dual purpose, producing bonus electricity in addition to its heat exchange design. When applied to the outside of a tube, the result is a thermoelectric generator in a versatile deployment vehicle for electric generation from hot and cold fluid streams and for geothermal deployments. A single such tube may be used for generating power, or multiple tubes may be used together in concert to increase generation power levels. This allows for flexibility in manufacture and deployment.

Critical to the operation of a thermoelectric generation device is the requirement for a temperature difference across the active thermoelectric material. This temperature difference may be maintained from conductive, convective and/or radiative heat transfer. In a tubular configuration, the tube may be placed in the air, placed in a liquid, embedded in the ground or placed within a solid heat transfer surface. A second fluid, which must have a different temperature from the outside environment into which the tube is deployed, may be passed continuously or in bursts through the middle of the tube. The temperature difference results in a voltage difference which is captured from wires connecting to the thermoelectric material that are used for electrical power delivery.

The tubular thermoelectric generator may be used within a heat exchanger. For example, all fossil-fueled and nuclear power plants using steam driven turbines have a type of heat exchanger called a surface condenser to convert exhaust from the turbines into water condensate which is then reused. Cooling water is passed through tubes that are placed in the path of the exhaust steam coming out of the turbines. A tubular thermoelectric generator can serve to extract electrical energy from the known temperature differential between the exhaust steam and the cooling water and thereby extract additional electrical energy from what would otherwise be waste heat. Another example of a heat exchanger is the radiator of a car, where a cooling solution (water and/or antifreeze) is pumped through the engine where it collects heat and then goes to the radiator where forced air (convention) cooling goes across cooling fins. By deploying thermoelectric tubes in the radiator, the thermal energy flowing between the heated cooling fluid and the outside air may be used to generate electrical energy and this could be used to augment the function of the car alternator.

A tubular configured thermoelectric generator lends itself to harvesting thermal energy that is collected from the sun. One possible use is in a solar pond. A solar pond is a body of water that contains layers of salt solutions. The top layer has low salt content, the bottom layer has high salt content and the intermediate layer has an intermediate salt content and establishes a density gradient that prevents heat exchange by natural convection. Incident solar radiation heats up the bottom layer. The top layer serves to insulate this layer.

The difference in temperature may be on the order of 60 or more degrees Celsius. If a thermoelectric generator is configured around a tube, that tube can be used to transport salty water from lower levels through the upper levels, effectively acting as a heat exchanger. Since the system is a closed one, and it is only necessary to transport the fluid a vertical distance of, perhaps, a few feet, the pumping requirements are minimal. In this way, electric generation can be accomplished from a solar pond and solar energy that is collected over a relatively large area may be “harvested” from a single tube generator.

Similar to the application in a solar pond, a tubular generator could be deployed in a roadway. A square meter of roadway receives just as much solar radiation as a square meter of photovoltaic panel, the challenge is in determining how to harvest that energy. A tubular generator that is deployed subsurface in a roadway can harvest the heat coming off that roadway. By passing a cool fluid through the generator, the temperature gradient through the wall can be used to generate electrical power.

Although the above discussion has been primarily directed at the use of spraycasting thermoelectric material onto a substrate to develop thermoelectric coated heat exchangers and tubular thermoelectric generators, the technique may be applied equally well to applications in thermoelectric cooling.

### BRIEF DESCRIPTION OF THE DRAWINGS

FIG. 1 depicts a side view of a multielement thermoelectric generator;

FIG. 2 depicts block of a multielement Peltier heat pump illustrating the symmetry between generation and refrigeration in a thermoelectric device;

FIG. 3 depicts a single element thermoelectric generator model that may be used to analyze the behavior of multielement thermoelectric devices and which highlights the thermal interfaces that impact overall thermoelectric performance;

FIG. 4 depicts energy flows in a composite thermoelectric generator;

FIG. 5 is a thermal resistance schematic model for a thermoelectric device;

FIG. 6 is an electrical schematic for a thermoelectric generator;

FIG. 7 is a plot for three cases contrasting generated power as a function of thermoelement length;

FIG. 8 is a block diagram for applying a powder to coat a substrate

FIG. 9 is a block diagram for a high velocity oxy-fuel system for applying a powder to coat a substrate

FIG. 10 shows a two nozzle system to spray coat a flat substrate

FIG. 11 shows a five nozzle system to spray coat a tubular substrate to build a tubular thermoelectric generator

FIG. 12 depicts options for a tubular fluid channel with fins to radiate heat

FIG. 13 illustrates the pattern with which conductors and thermoelectric material may be applied to a flat surface to create a thermoelectric generator

FIG. 14 depicts a tube with a dielectric coating applied as the fist step in producing a tubular thermoelectric generator

FIG. 15 depicts the next step in producing a tubular thermoelectric generator in which an electrically conductive layer is applied

FIG. 16 depicts the next step in producing a tubular thermoelectric generator in which N-type and P-type thermoelectric coatings are applied

FIG. 17 depicts an outside view and a cutaway of a complete, two-couple thermoelectric generator.

FIG. 18 depicts a method for coating a substrate to produce a thermoelectric generator that does not require the application of a separate electrically conductive coating

FIG. 19 depicts a two-couple thermoelectric generator that is analyzed in four longitudinal sections

FIG. 20 depicts an electrical schematic for a lumped model of a two-couple thermoelectric generator

FIG. 21 depicts the tubular thermoelectric generator as used in a condenser application.

FIG. 22 depicts the tubular thermoelectric generator as used in a solar pond

FIG. 23 depicts the tubular thermoelectric generator as used to harvest solar energy from a roadway

FIG. 24 depicts a tubular thermoelectric generator that is used to directly capture solar energy within a vacuum bottle.

### LIST OF REFERENCE NUMERALS

10—Topside electrical conductor
11—Topside electrical insulating scaffold
12—n type thermoelement
13—Bottomside electrical insulating scaffold
14—p type thermoelement
15—Bottomside electrical insulating scaffold
16—Heat source
18—Heat sink
19—Electrical conductor
20—Electrical load
21—Electrical insulator
22—Voltage source
24—First side
26—Second side
28—n type thermoelement
30—p type thermoelement
32—Heat reservoir
34—Electrical insulator
36—Electrical conductor
38—Thermoelectric element
40—Electrical conductor
41—Electrical conductor
42—Electrical insulator
43—Electrical insulator
44—Colder reservoir
45—Electrical conductor
46—Interface between electrical insulator and electrical conductor
47—Electrical insulator
48—Interface between electrical conductor and thermoelectric material
49—Node representing the hot reservoir
50—Thermal contact resistance between hot reservoir and hot side insulator
51—Lumped thermal resistance in hot side insulator
52—Thermal contact resistance between hot side insulator and electrical conductor
54—Lumped thermal resistance in hot side electrical conductor
55—Equivalent series thermal resistance
56—Thermal contact resistance between hot side electrical conductor and thermoelement
57—Node representing the hot side of thermoelement
58—Lumped thermal resistance in thermoelement
59—Node representing the cold side of thermoelement
60—Thermal contact resistance between thermoelement and cold side electrical conductor
62—Lumped thermal resistance in cold side electrical conductor
64—Thermal contact resistance between cold side electrical conductor and insulator
66—Lumped thermal resistance in cold side insulator
68—Thermal contact resistance between cold side insulator and cold reservoir
70—Node representing the cold reservoir
72—Equivalent thermal resistance on hot side
74—Equivalent thermal resistance on cold side
76—Thermoelement electrical resistance
78—Total contact and conductor electrical resistance
80—Load
81—Terminal
82—Ideal voltage source
83—Terminal
84—Compressed gas
86—Preheater
88—Powder container
90—Mixing stage
92—Nozzle
94—Spray
96—Substrate
98—Plasma generator
100—Oxygen gas
102—Acetylene gas
108—First nozzle
110—Second nozzle
112—X-axis
114—Y-axis
116—Flat substrate
118—Spray outline for nozzle 1
120—Spray outline for nozzle 2
122—x axis
124—Round tube
126—Axis of rotation
128—X-axis
130—Carrier with controllable nozzles
132—Spray for dielectric 1
134—Spray for conductor
137—Nozzle for dielectric 1
138—Nozzle for conductor
139—Nozzle for dielectric 2
140—Nozzle for N-type thermoelectric material
141—Nozzle for P-type thermoelectric material
142—Portion of tube with conductor sprayed over dielectric
143—Portion of tube with dielectric 1 applied
144—Fluid entry
146—Fluid exit
148—Fluid conduit
150—Fin
152—Surface of fin
154—Base of fin in cross-sectional view
156—Tip of fin in cross-sectional view
158—Fluid channel
160—Internal fins
162—Outside wall of tube
164—Tube with internal fins
165—Surface of fin
166—Bottom conductive coating
167—Fin
168—n type coating
170—p type coating
171—Top conductor coating
172—Electrical terminal 1
174—Electrical terminal 2
176—Other side of fin
177—Tube
178—Dielectric coating
179—Tube wall
180—Conductive coating
181—Gap between conductive rings
182—P-type thermoelectric layer
183—N-type thermoelectric layer
184—Gap between P-type and N-type layers
185—Second dielectric layer
186—Topside conductor layer
187—Electrical terminal
188—Electrical terminal
190—Cold water in
191—Warmer water out
192—Steam
193—Water droplets
194—Tubular thermoelectric generator
195—Catch basin
196—Sun
197—Solar pond
198—Surface of pond
199—Upper layer of fluid
200—Lower layer of fluid
201—Boundary between salt layers
202—Top thermoelectric generator
204—Bottom thermoelectric generator
206—Pump
208—Sun
210—Roadway surface
212—Thermoelectric generator
214—Subsurface reservoir
216—DC to AC convertor
218—Power line
220—Earth
222—Upper pavement
224—Tubular thermoelectric generator
226—Fluid intake
228—Fluid outtake
230—Evacuated container
232—Sun
234—Automatic flush valve
236—Light emitter
238—Light detector
240—Water input
242—Water output
244—Input pipe
246—Output pipe
248—Light beam
250—Substrate
252—Dielectric layer
254—Lower electrical insulator
255—Upper electrical insulator
256—n type thermoelectric material
258—p type thermoelectric material
260—Heat flow
262—Electrical current
265—Proximal end of tube
266—Longitudinal section of tube generator
267—Distal end of tube
268—Longitudinal section of tube generator
270—Longitudinal section of tube generator
272—Electrical terminal
274—Conductor joining P to N
276—Conductor joining N to P
278—Conductor joining P to N
280—Electrical terminal
282—Direct electrical connection
284—P thermoelement
286—N thermoelement
288—Electrical Conductor
290—N thermoelement
292—N thermoelement
294—N thermoelement
296—N thermoelement

### DESCRIPTION OF THE PREFERRED EMBODIMENTS

In the following paragraphs, the present invention will be described in detail through examples and detailed drawings. Definitions of some of the terms used in describing the preferred embodiments are as follows:

Carnot limit—by the second law of thermodynamics, the theoretical limit on the ability of a device to convert thermal energy into work. The Carnot efficiency limit is given by η=(T_{H}−T_{C})/T_{H} where T_{H} and T_{C} are, respectively, the temperatures of the hot (source) and cold (sink) reservoirs.
Cold and hot side temperature—terms like hot reservoir, hotter side, cold side and colder reservoir are relative terms. In some implementations, the “hot” side of a thermoelectric device might be at ambient temperature while the “cold”side is at a cooler temperature than ambient. In other implementations, the “cold” side might be at ambient temperature while the “hot” is at a warmer than ambient temperature. In still other implementations, the terms “hot” and “cold” might have no relationship to ambient temperature but with “hot” always denoting a higher temperature than “cold”.
Couple—a series connection of one P-type and one N-type thermoelement
Dielectric—an electrically insulating material.
Efficiency—the power generated by a system divided by the power fed into it, a measure of how well a device converts one form of energy into another.
Figure of merit—the thermoelectric figure of merit is Z=σS²/λ, where σ is electrical conductivity, S is Seebeck coefficient and λ is thermal conductivity. Z has the units of K⁻¹ where K is degrees Kelvin.
Fluid—phases of matter in a liquid or gaseous state, examples including distilled water, salt water, alcohol, water vapor (steam), air or nitrogen.
Fourier law of heat transfer—defines the relationship between heat conduction through an object and the associated temperature gradient across that object and is given by Q=ΔT/R_{T}, where Q is heat flux in Joules/sec, ΔT is the temperature difference across the object in degrees Kelvin and R_{T} is the thermal resistance of the object in degrees Kelvin/watt.
Heat source and heat sink—For a thermoelectric module situated between two thermal reservoirs, the heat source is the reservoir having a higher temperature while the heat sink has a lower temperature. The direction of heat energy flow is from the heat source to the heat sink.
Heat exchanger—A device for transferring heat energy from one material to a second material without mixing the materials.
Heat flux—The heat energy flow across a boundary per unit time. The units of heat flux are Joules/sec or watts.
N-type thermoelectric material—n type (equivalently, N type or N doped) thermoelectric material is a metal, semimetal or semiconductor that is used for thermoelectric applications and for which the majority electrical carriers are electrons.
P-type thermoelectric material—p type (equivalently, P type or P doped) thermoelectric material is a metal, semimetal or semiconductor that is used for thermoelectric applications and for which the majority electrical carriers are holes.
Seebeck coefficient—the voltage that is generated in a material when it is subjected to a temperature difference of one degree Kelvin. The units are Volts per Kelvin.
Spraycasting—Also known as thermal spray coating, flame spray coating or metal spray coating. A technique to deposit one solid material on top of another whereby the coating is applied by ejecting a high velocity heated powder onto a target surface so that the powder fuses into a solid with a good mechanical and thermal connection.
Thermal conductivity—the inherent property of a material that specifies the amount of heat transferred through a material of unit cross-section and unit thickness for a unit temperature gradient. Thermal conductivity is measured in watts/m-K. Although thermal conductivity is an inherent property of a material, it depends upon the measurement temperature. The thermal conductivity of air is about 50% higher than the thermal conductivity of water vapor, whereas the thermal conductivity of liquid water is about 25 times that of air.
Thermal reservoir—A body of sufficient mass that the removal of a small amount of heat energy does not result in an appreciable temperature change.

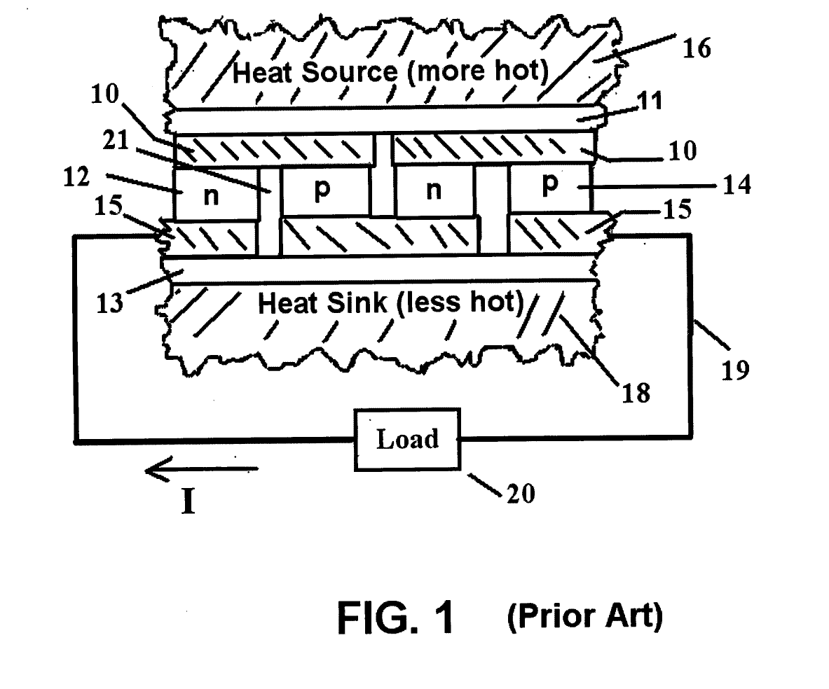

FIG. 1 depicts the side view of a thermoelectric generator. This generator is constructed by sandwiching specially chosen n-type and p-type conductor or semiconductor material 12 and 14 between noncontinuous electrical conductors 10. Although thermoelements 12 and 14 may be built using conductors such as bismuth and antimony, higher efficiency thermoelectrics are built using heavily doped semiconductors. N doped semiconductor thermoelectric material has the property that it converts a portion of the heat flux (heat energy flowing through it) into electricity, with the majority electrical carrier being electrons. P doped semiconductor thermoelectric material has the property that it converts a portion of the heat flux into electricity with the majority electrical carrier being holes. The electrical conductors 10 are chosen to be good conductors of both electricity and heat. The n and p type thermoelectric elements, 12 and 14, are separated from one another by electrical insulator 21. In many embodiments, electrical insulator 21 may simply be implemented by a small air or vacuum gap, in which the physical separation impedes the transfer of charge carriers between n and p. In some embodiments, electrical insulator 21 may be fashioned by using a silica aerogel or by using an organic material such as polyethylene or polyimide. When the thermoelectric device is placed between a heat source 16 and a heat sink 18, there is a flow of heat energy from the source 16 to the sink 18. Optional topside electrical insulating scaffold 11 serves as a mechanical support that holds the topside electrical conductors 10 in place and prevents electrical shorting from taking place between the topside electrical conductors 10 and the heat source 16. In a similar way, optional bottomside electrical insulating scaffold 13 supports the bottomside electrical conductors 15 and prevents electrical short circuiting to the heat sink 18. It should be noted that the term “topside” and “bottomside” has significance only in terms of FIG. 1. Electrical insulating scaffolds 11 and 13 are said to be optional because in some embodiments, they will be unnecessary, for example, when electrical conductors 10 and 15 can provide sufficient mechanical support and the thermal reservoirs 16 and 18 are not electrically conducting.

In most embodiments, heat source 16 represents a thermal reservoir containing heat energy at some temperature, T_{H}. In this case, heat source 16 could be a solid, liquid or a gas, transferring its energy to the thermoelectric device by conduction and convective (for a gas or liquid) means. In some embodiments, heat source 16 might transfer energy to the thermoelectric exclusively through radiative heat transfer, in which case the body labeled 16 in FIG. 1 could be a vacuum with radiative heat transfer occurring between some external source, impinging upon scaffold 11 and thereby providing heat energy to the thermoelectric device. Likewise, the heat sink 18 can be a solid body or a body of liquid or gas, having a lower temperature T_{C} than that of the heat source 16, that is T_{C}<T_{H}. In some cases, the heat sink 18, might not be in mechanical contact with the bottomside electrical insulating scaffold 13, but might be remote, in which case heat removal from the bottomside electrical insulating scaffold 13 would be by means of radiating heat to a cooler environment.

In FIG. 1, the thermoelements are connected in electrical series and thermal parallel. As heat flows from the heat source 16 to the heat sink 18, the charge carriers (electrons for n type material and holes for p type material) flow in the direction of the heat flow. This results in an electrical current, I, which flows through a conductor 19 to an attached electrical load 20. Electrical load 20 may be a resistive load such as a heater or an incandescent light, or it can be an electronic converter unit that converts the electrical power produced by the thermoelectric device into a different form. For example, the electronic converter could be used to do voltage conversion from one direct current level to another, or to transform direct current into alternating current. As part of the conversion process, the electronic converter could be used to match the internal resistance of the thermoelectric generator in order to effect maximum power transfer. If the temperature differential across a thermoelectric device is reversed in polarity, then the generated voltage will be reversed in polarity and the direction of current flow through an attached load will be reversed.

A key figure-of-merit for thermoelectric materials is the so-called “Z” which was given in equation (1). Generation efficiency increases with Z and so, in general, high values of Z are desirable and this provides a roadmap for improving thermoelectric performance, namely, increase σ and S and decrease λ. At temperatures in the range of 250K to 400K, alloys of bismuth-telluride exhibit the highest values of Z. N and p type bismuth-telluride thermoelectric elements may be produced by heavy doping with selenium and antimony respectively. Published example stochiometries for n and p type thermoelectrics are given in Thermoelectrics Handbook, Macro to Nano, D. M. Rowe, editor, CRC Press, Boca Raton, Fla., 2006, p. 27-9 as (Bi₂Te₃)₉₅(Bi₂Se₃)₅ for n type and (Bi₂Te₃)₇₅(Sb₂Te₃)₂₅ for p type.

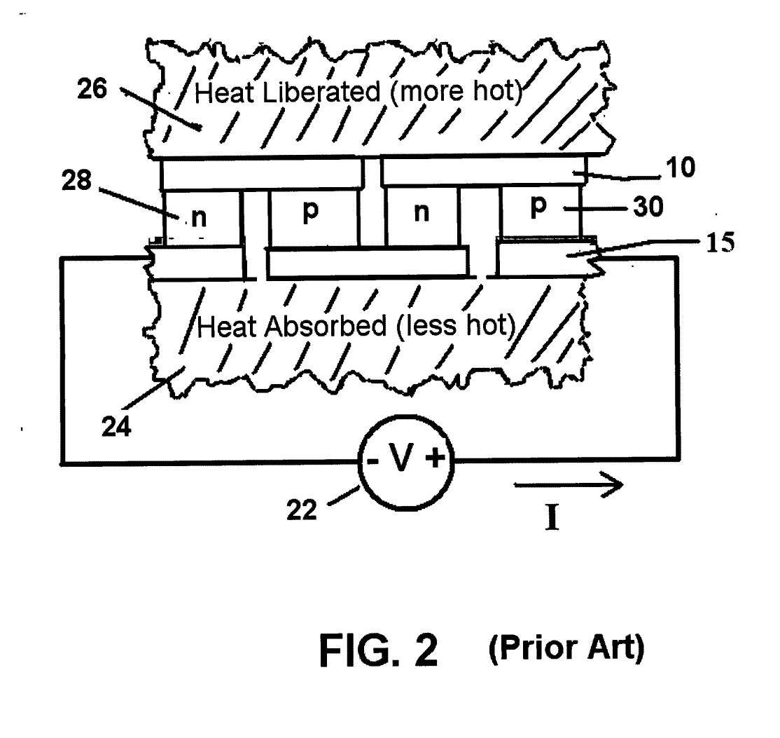

FIG. 2 depicts a Peltier heat pump. This is a thermoelectric device that can be of identical construction to the thermoelectric generator of FIG. 1, with the difference being that instead of a load, there is a voltage source 22 that causes current flow. The coupling between heat currents and electrical currents in a thermoelectric device results in the movement of heat from a first side 24 of the device to a second side 26 with the result that the first side 24 becomes cooler than the ambient temperature and the second side 26 becomes warmer than the ambient temperature. If the applied voltage source 22 changes polarity, then the heat movement will be in the opposite direction. Status quo Peltier heat pumps and thermoelectric generators are generally constructed from assembling a large number of discrete N-type and P-type thermoelements together in an electrical circuit. One problem with this approach is that when it is desirable to have thin thermoelements (eg: the thermoelement length is short), it is difficult to carry out manufacturing and interface effects at soldered connections can overwhelm the thermoelectric properties.

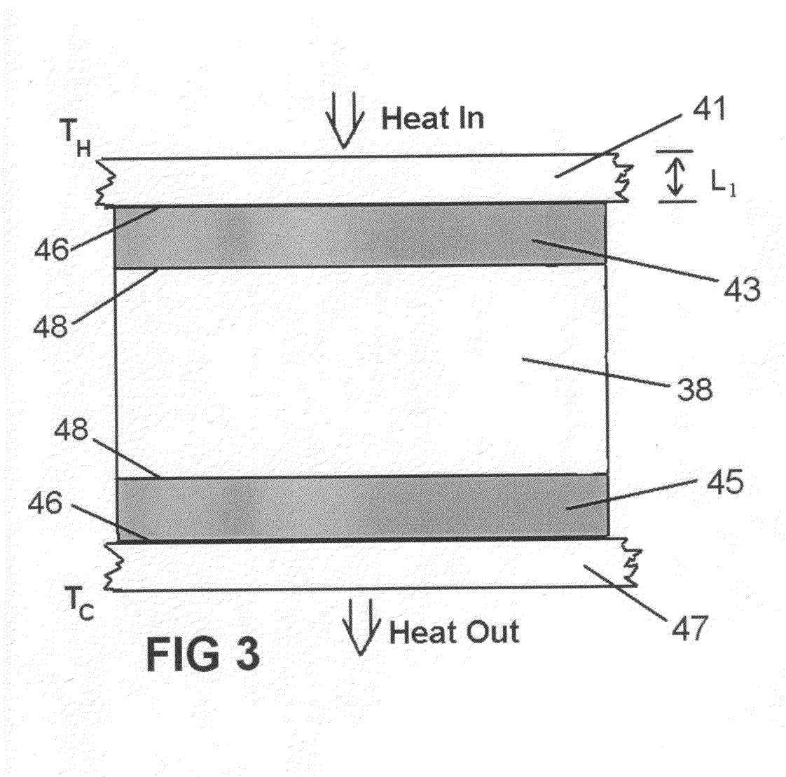

FIG. 3 depicts a single thermoelectric cell. Although practical thermoelectric devices are constructed from a number of such cells, the relevant issues may be highlighted by inspecting a single cell. The cell in FIG. 3 is made up of 5 layers. From the top, there is an electrical insulator 41, then an electrical conductor 43 then the active thermoelectric element 38 then a second electrical conductor 45 and a second electrical insulator 47. Both electrical resistance and thermal resistance within any of these five layers are dependent on both material and geometry according to the relationship

$$R = \frac{ρ L}{A} \qquad ( 8 )$$

where R has the units of ohms for electrical resistance and ° K/watt for thermal resistance, ρ is a material property called resistivity (units of ohms-m for electrical resistivity and m° K/Watt for thermal resistivity), L is the length of the element in meters and A is the cross-sectional area in square meters. In a thermoelement, the electrical resistivity is the reciprocal of electrical conductivity σ. Likewise, in a thermoelement, the thermal resistivity is the reciprocal of thermal conductivity λ. Any thermal resistance impedes the delivery of heat energy to the thermoelectric element 38 and is undesirable. For this reason, it is desirable that the electrical insulators and electrical conductors have a very low thermal resistance. In FIG. 3, the length of the top electrical insulator 41 is shown to be L₁. The electrical insulator 41 should have high electrical resistance and low thermal resistance. As seen in equation (8), for a given cross-sectional area, the resistance will be a function of the product ρL₁, where thermal resistivity and electrical resistivity must both be considered. Given any candidate material for the top electrical insulator 41, resistance can always be increased/decreased by increasing/decreasing the length L₁. One electrical insulator that is often used in thermoelectric devices is aluminum oxide (Al₂O₃) which is also known as alumina. Alumina is a good electrical insulator, has a reasonably low thermal resistivity and is generally deployed with a length dimension that is chosen to provide mechanical strength to the complete multielement module. The electrical conductor 43 may be fabricated from many candidate metals. Nickel, aluminum, tin and plated copper are popular choices. Good electrical conductors are inherently good thermal conductors because they allow significant heat transport via electron movement. A critical element of a good thermoelectric design is to minimize the interface resistances, both electrical and thermal, at locations 46 and 48 where dissimilar materials are joined.

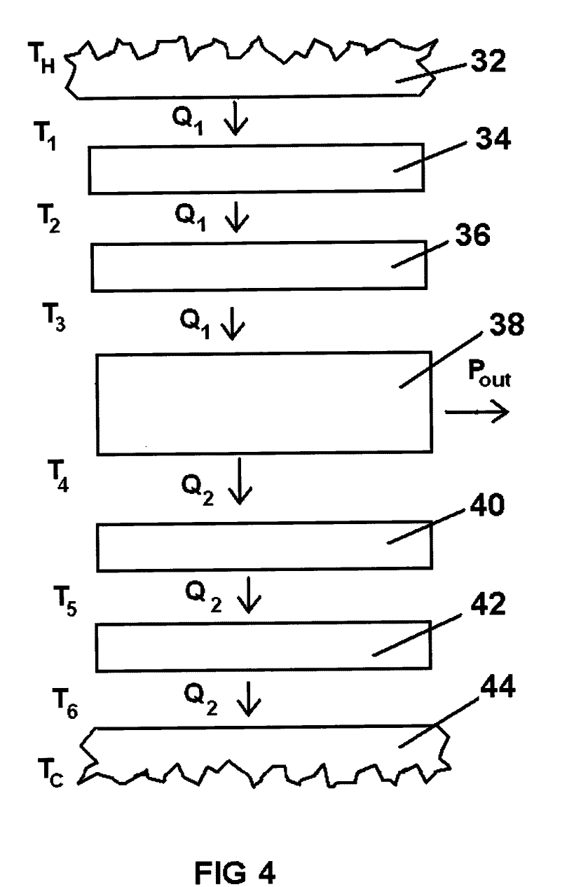

FIG. 4 depicts a block diagram which is helpful in developing energy balances that characterize thermoelectric generator performance. This is a composite model and lumps the various components of a multielement thermoelectric generator into an equivalent single element model. A heat reservoir 32 having temperature T_{H} serves as the source of heat energy for the system. Heat reservoir 32 may be a solid body that receives a constant influx of energy that serves to maintain the temperature T_{H} in spite of heat losses to the thermoelectric element. An example of a solid body would be a road pavement that maintains a higher temperature than the ambient air due to the absorption of solar energy. Another example of a solid body that could serve as heat reservoir 32 would be subsurface ground that would maintain a temperature T_{H} due to geothermal sources. Instead of a solid body, heat reservoir 32 might be a body of fluid such as steam in a heat exchanger or water in a car radiator.

Since the heat capacity of fluids is generally much lower than that of solids, in order for a fluid heat reservoir 32 to maintain a constant temperature T_{H}, the fluid must be moving, replenishing the heat energy flux Q₁ that moves into the thermoelectric device. In some embodiments, the heat reservoir 32 might be modeled as a massless construct that receives thermal energy from radiative means. Examples would be solar or laser heating of a thermoelectric device that is in a vacuum. In those cases, the thermal energy is delivered to the composite model through radiative means. The heat energy flux Q₁ passes from the heat reservoir 32 to electrical insulator 34. The units for Q₁ are in Joules/sec, or watts. The electrical insulator 34 serves to isolate the electrical conductor 36 from the heat reservoir 32. For example, if the heat reservoir 32 consists of a body of salt water, then since salt water is an electrical conductor, it could serve to cause electrical short circuits. The electrical insulator 34 prevents this event and, as discussed previously, may serve as a scaffolding, offering mechanical support to the thermoelectric device. The electrical conductor 40 and electrical insulator 42 that are near the colder reservoir 44 serve similar functions as their hot side counterparts, 36 and 34 respectively.

In FIG. 4, the thermoelectric element 38 is the actual energy converter. All of the heat energy flux Q₁ that exits the electrical conductor enters the thermoelectric element 38. The temperature difference across element 38 is used to generate an electrical power Pₒᵤₜ. When the thermoelectric element generates power, the heat energy flux Q₂ that exits the thermoelectric element 38 is less than the heat energy flux Q₁ that enters the thermoelectric element 38. An energy balance reveals the relationship Q₁=Q₂+Pₒᵤₜ. The temperatures T₁, T₂, T₃, T₄, T₅, T₆ are intermediate temperatures within the composite model and satisfy the relationship T_{H}≧T₁≧T₂≧T₃≧T₄≧T₅≧T₆≧T_{C}. An implicit assumption in this model is that there are no thermal contact resistances. For example, the model suggests that that the temperature of the bottom of electrical insulator 34 is T2, which is the same as the temperature of the top of electrical conductor 36. This is an oversimplification. In reality, there will be contact resistances at any material interface. These can often be reduced by a proper surface treatment, but can still result in significant temperature drops. The active portion of the thermoelectric generator is the thermoelectric element 38. This is the part that does the energy conversion. It is desirable to keep as large a temperature difference T₃−T₄ as possible across the thermoelectric element 38. To do this, it is desirable to minimize the thermal resistances between points of common temperature T_{H} and points of common temperature T₃. In the very best case (thermal resistance equals zero between reservoir and thermoelectric), T_{H}=T₃. Similarly, it is desirable to reduce thermal drops between points of common T₄ and the temperature of the colder reservoir 44. In the best case, T₄=T_{c}.

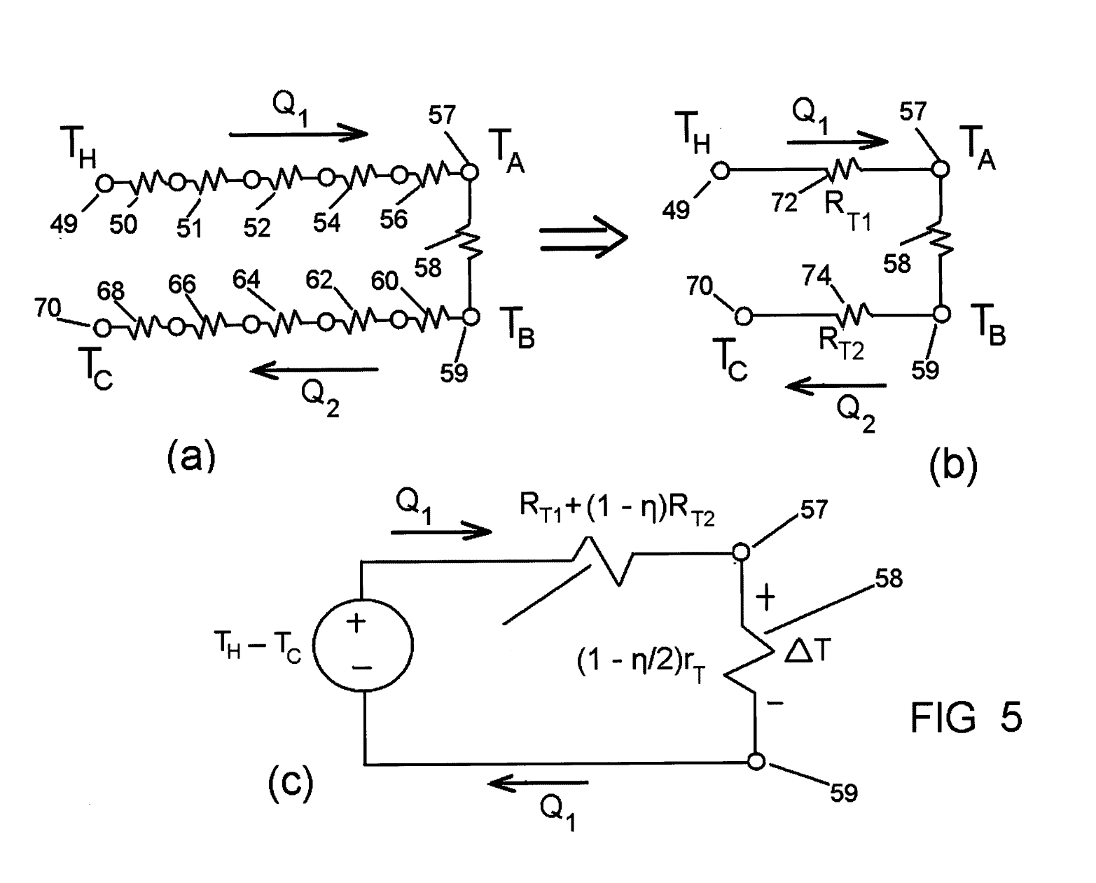

FIG. 5 depicts a thermal schematic showing the heat energy flow through the thermal “circuit”. In FIG. 5(a), heat energy flux Q₁ flows from the node 49 representing the hot side reservoir through the contact resistance 50 between hot side reservoir and the hot side electrical insulator, through the thermal resistance 51 of the hot side insulator, then through the contact resistance 52 between hot side electrical insulator and hot side electrical conductor, then through the thermal resistance 54 of the hot side electrical conductor, then through the contact resistance 56 between the hot side electrical conductor and the thermoelement and into the node 57 at the hot side of the thermoelement. Thermal resistances 50, 51, 52, 54 and 56 all have the same heat energy flux Q₁ passing through them and are considered to be in thermal series. Some of the heat energy flux Q₁ that enters node 57 will be converted to electrical power by the thermoelectric element. For this reason, the magnitude of the heat energy flux Q₂ leaving the thermoelectric element at node 59 will be smaller than the flux Q₁ that enters node 57. Energy heat flux Q₂ passes through the contact resistance 60 between the thermoelectric element and the cold side electrical conductor then through the thermal resistance 62 of the cold side electrical conductor then through the contact resistance 64 between the cold side electrical conductor and the cold side electrical insulator then through the thermal resistance 66 of the cold side electrical insulator then through the contact resistance 68 between the cold side electrical insulator and the cold reservoir and out of node 70 which represents the cold reservoir. Since thermal resistances 60, 62, 64, 66 and 68 all have the same heat energy flux Q₂ passing through them, they are considered to be in thermal series. By combining thermal series resistances, the model in FIG. 5(a) can be simplified to that in FIG. 5(b), where R_{T1} 72 is the sum of hot side thermal resistances 50, 51, 52, 54 and 56. In a similar way, R_{T2} 74 is the sum of cold side thermal resistances 60, 62, 64, 66 and 68.

The open circuit voltage that is generated by a thermoelectric element is proportional to the temperature gradient across that element. The constant of proportionality is the so-called Seebeck coefficient, so

V_{OC}=SΔT (9)

where S is the Seebeck coefficient in volts/degree K, and ΔT is the difference in temperature across the thermoelectric element, equivalently, the difference in temperature between nodes 57 and 59 in FIG. 5. For any given hot and cold reservoir temperatures T_{H} and T_{C}, an important design goal is to maximize the difference in temperature between nodes 57 and 59. Using the Fourier law, the temperature drop between nodes 49 and 57 is Q₁R_{T1} and the temperature drop between nodes 59 and 70 is Q₂R_{T2}. Since the sum of temperature drops around a closed circuit must equal zero, the temperature drop between nodes 57 and 59 may be expressed as

ΔT=T_{H}−Q₁R_{T1}−Q₂R_{T2}−T_{C}. (10)

From this equation, it may be seen that for a constant T_{C}, T_{H} and given thermoelectric element (which influences Q₁ and Q₂), ΔT is maximized by minimizing the thermal resistances R_{T1} 72 and R_{T2} 74. Two observations may be made about the thermal circuit in FIG. 5. First, it is the total series thermal resistances R_{T1} 72 and R_{T2} 74 that are important in determining ΔT rather than the individual elements of R_{T1} or R_{T2}. So, for example, if the thermal resistance 51 in the hot side electrical insulator is reduced by some amount but the thermal contact resistance 56 between the hot side electrical conductor and the thermoelement is increased by the same amount, the total hot side thermal resistance R_{T1} 72 is unchanged and there is no net impact upon ΔT. Second, the thermal resistances 50, 51, 52, 54, 56 on the hot side of the thermoelectric circuit have more influence on ΔT than the cold side thermal resistances 60, 62, 64, 66, 68. This is because during thermoelectric generation, Q₂<Q₁. So, for example, because it is multiplied by Q₁, an increase in R_{T1} by 1° K/watt is more detrimental to the value of ΔT and hence generated voltage than a similar increase in R_{T2} (which is multiplied by Q₂ to derive a cold side temperature drop).

Noting that

Q₂=(1−η)Q₁ (11)

where η=P/Q₁ is the conversion efficiency, an equivalent thermal circuit may be drawn as shown in FIG. 5(c) where the average heat flux through the thermoelement 58 is (Q₁+Q₂)/2 and the thermoelement 58 has a thermal resistance of

$${r}_{T} = \frac{L}{λ A} . \qquad ( 12 )$$

Then the temperature drop across the thermoelement 58 may be expressed as

$$Δ T = \frac{( {T}_{H} - {T}_{C} ) DL}{DL + C λ A} , \\ where \\ D = 1 - \frac{η}{2} , C = {R}_{T 1} + ( 1 - η ) {R}_{T 2} . \qquad ( 13 )$$

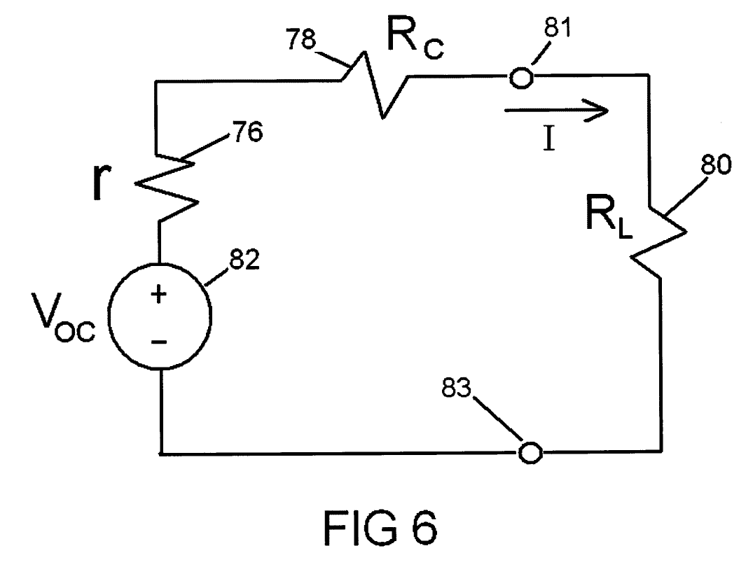

FIG. 6 depicts a Thevenin equivalent model for a voltage source. The terminals 81,83 of the voltage source are the connection points to which an external load 80 may be attached. The voltage source model consists of an ideal voltage source 82 plus an internal resistance which is composed of the sum of the electrical resistance of the thermoelement 76 together with the sum 78 of all series connected electrical contact resistances within the circuit as well as all series connected electrical conductor resistances in the circuit. The load 80 represents the electrical load to which useful power is delivered. Although the load will be described as being a resistor, in many applications it will have another form, such as a power converter which transforms direct current from the thermoelectric generator into an alternating current that may be transmitted remotely or used to power motors, electronics, lighting or a wide variety of electrical devices. Using the model in FIG. 6 for a single thermoelement, when a temperature difference is applied across the thermoelement, it produces a load current of

$$I = \frac{S Δ T}{r + {R}_{C} + {R}_{L}} \qquad ( 14 )$$

In order to obtain maximum power transfer to the load R_{L}, the load must be chosen to be equal to the internal resistances in the model in FIG. 6, so choose

R_{L}=r+R_{C}. (15)

The internal electrical resistance of the thermoelement is

$$r = \frac{L}{σ A} , \qquad ( 16 )$$

where L is the length of the thermoelement and A is the cross-sectional area of the element. Substituting (13), (15) and (16) into (14) allows the derivation of an expression for load power, I²R_{L}, as a function of the thermoelectric length as

$$P = {I}^{2} {R}_{L} = \frac{{{S}^{2} ( {T}_{H} - {T}_{C} )}^{2} {D}^{2}}{4} \times \frac{{L}^{2}}{( \frac{L}{σ A} + {R}_{C} ) {( DL + C λ A )}^{2}} \qquad ( 17 )$$

By differentiating (17) with respect to L and finding the maximum, the thermoelement length L that yields the maximum power output is found as the solution to the third order polynomial

$$\frac{{( 1 - η / 2 )}^{2}}{σ A} {L}^{3} - ( \frac{{C}^{2} {λ}^{2} A}{σ} + 2 ( 1 - η / 2 ) ( C λ A ) {R}_{C} ) L - 2 {{R}_{C} ( C λ A )}^{2} = 0 \qquad ( 18 )$$

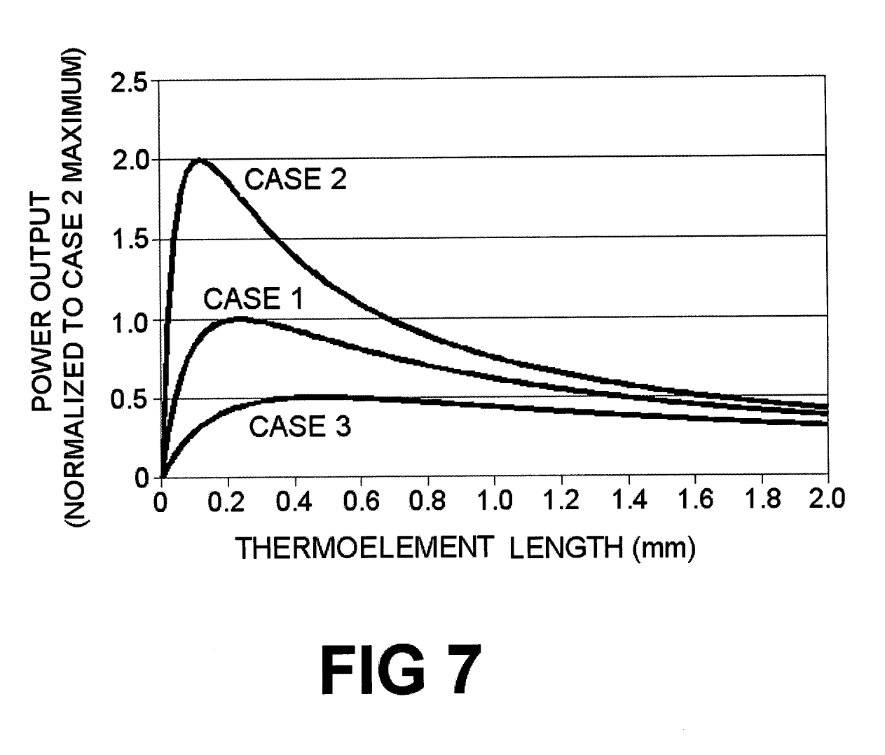

FIG. 7 depicts a plot of three case studies for power output as a function of thermoelectric length L. This length, L, is the dimension of the thermoelement that is in the direction of heat flow though the thermoelement. These plots were generated using equation (17) and then normalizing all plots to the Case 1 maximum. Table 1 summarizes the parameters

| PARAMETER | VALUE |
|---|---|
| Thermoelement Seebeck coefficient, S | 2.0e−4 V/°K |
| Thermoelement electrical conductivity, σ | 1.0e5 Ω⁻¹m⁻¹ |
| Thermoelement thermal conductivity, λ | 1.5 W/m ° |
| Hot side temperature, T_{H} | 400° K |
| Cold side temperature, T_{C} | 300° K |
| Area, A | 5.0e−4 m² |
| Electrical parasitic resistances, R_{C} | 1.0e−8 Ω |
| Conversion efficiency, η | 0.05 (5%) |

1—Parameters for Case Study on Thermoelement Length
   The three cases correspond to three different parasitic thermal resistances, C. For Case 1, C=0.3° K/W. This is an equivalent amount of thermal resistance to the case of a stainless steel substrate having a 2.54 mm wall thickness. For Case 2, the effective thermal resistance was cut in half, to C=0.15° K/W. For Case 3, the effective thermal resistance was doubled over that of Case 1, to C=0.6° K/W. For each case, a calculation of power output was made as a function of the length (equivalently, the layer thickness) of the thermoelement. As expected, for each of the three cases, there is an optimal thermoelectric length. For Case 1, this optimal occurs for a length of 0.24 mm. For Case 2, the optimal occurs for a length of 0.12 mm and results in double the maximum power output. For Case 3, the optimal length is 0.48 mm and results in half the maximum power output. In all three cases, the curve is very steep for thermoelectric lengths that are less than the optimal and rolls off more slowly for lengths that are longer than the optimal. What this suggests is that within manufacturing tolerances, it is better to design for mean thermoelement lengths that are slightly longer than the length which yields the maximum power.

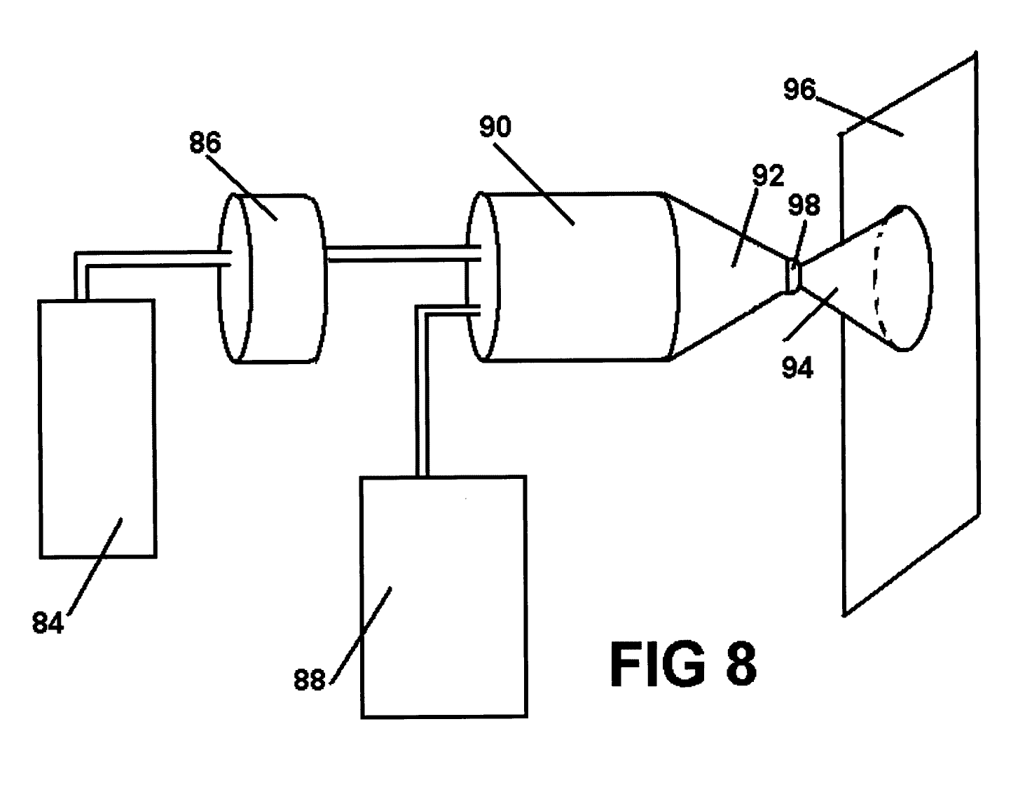

FIG. 8 depicts an apparatus for applying coatings to a substrate. A gas is delivered from a compressed gas source 84 to a preheater 86 which heats the gas. A powder container 88 holds the material to be deposited in a powder form. Mixer 90 combines the gas and powder and accelerates the powder particles through a nozzle 92. A spray 94 containing the particles in a gas stream is then directed to a substrate 96. In some embodiments, the nozzle 92 may be moved parallel to a motionless substrate 96 in order to make an even deposition. In other embodiments, the substrate 96 may be moved while nozzle 92 is held stationary. The powder size, gas flow rate, setting of the preheater 86 and velocity of the particles leaving the nozzle 92 are chosen so that the kinetic energy of the powder particles in the spray 94 are sufficient to bond to the substrate 96 or with other deposition layers as they deform and combine upon impact. In some embodiments, a plasma generation unit 98 is used to heat up powder particles to a very high temperature as they exit the nozzle 92. The process depicted in FIG. 8 is generically referred to as a spraycasting technique. Such techniques are unique because they do not require a phase change of the material to be applied. The material to be applied is not melted or vaporized. The process does not require a vacuum. With the correct choice of materials and process parameters, dissimilar coatings can be applied upon one another with intimate bonding and without the requirement for intermediate solders or adhesives. With spraycasting, dense and even layers of material can be applied to a substrate with a controllable thickness. When used for applying thermoelectric coatings, spraycast techniques make possible much thinner (shorter in thermoelectric length) thermoelectric devices than are possible when using discrete thermoelement pellets. This makes spraycasting a versatile technique for manufacturing thermoelectric devices.

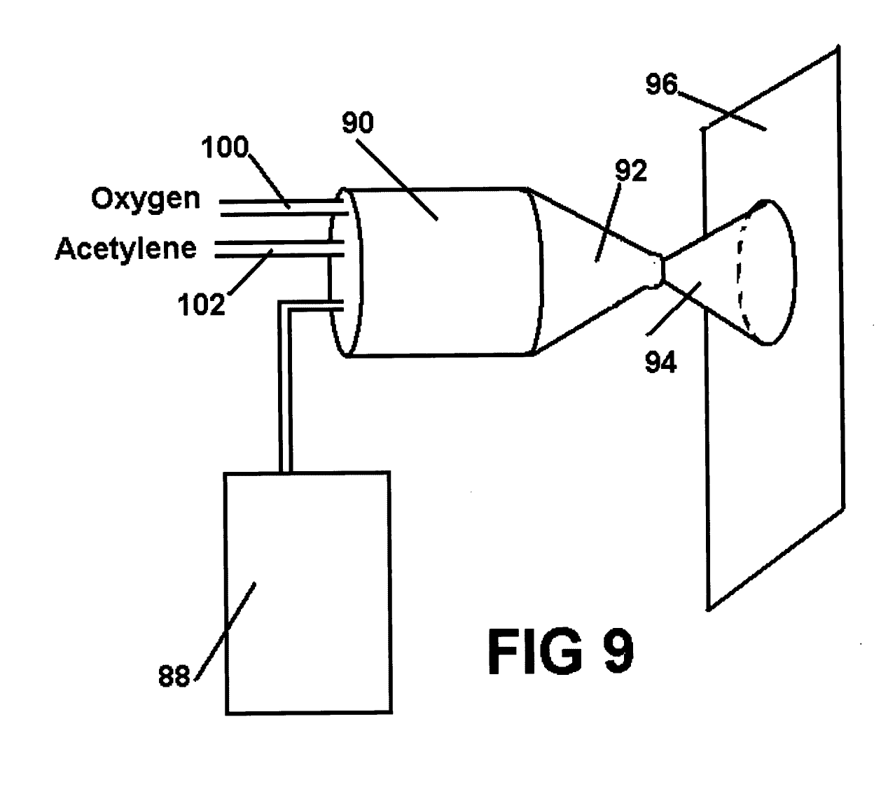

FIG. 9 depicts a high velocity oxy-fuel (HVOF) technique for applying coatings to a substrate. Oxygen gas 100 and acetylene gas 102 are combined in mixer 90 and combusted with an igniter (not shown). This creates a very high heat condition. Powder from the powder container 88 is mixed in and the combustion gases serve to accelerate the powder particles through the nozzle 92 and into a spray 94 onto the substrate target 96.

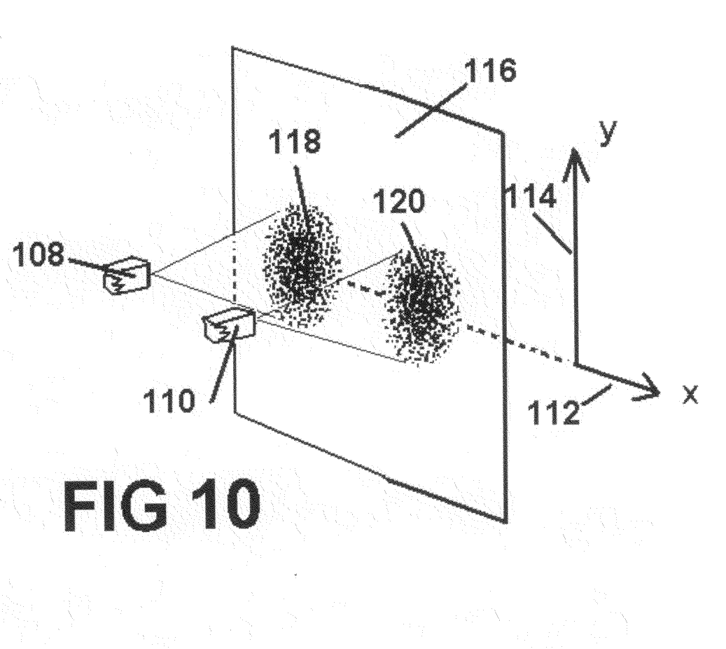

FIG. 10 depicts a flat substrate 116 onto which two thermal sprays are directed. The first nozzle 108 directs one material onto substrate 116. The second nozzle 110 directs either the same or a different material onto substrate 116. When substrate 116 is motionless relative to nozzles 108 and 110, the regions which are coated by nozzles 108 and 110 are, respectively, 118 and 120. The coating thickness that is laid down is not uniform, but will have regions of thicker application. This will generally be the center region and is illustrated in FIG. 10 by darker regions within spray outlines 118 and 120. By moving nozzles 108 and 110 in the x axis 112, the coated regions 118 and 120 may be spread in the x direction. By moving nozzles 108 and 110 in the y axis 114, the coated regions 118 and 120 may be spread in the y direction. By turning nozzles 108 and 110 on or off in a programmed manner, an arbitrary pattern of layers of coatings may be applied to substrate 116. As an alternative, nozzles 108 and 110 could be held stationary and substrate 116 could be moved in the x and y directions under programmed control to receive a given pattern of coatings. By applying strips of coating in the x (equivalently y) direction, with each strip offset slightly in the y (equivalently x) direction, it is possible to apply areas of largely uniform thickness with reductions in coating thickness along the edges. This approach favors the application of regions with a large dimension relative to the diameter of the spray outlines 118 and 120.

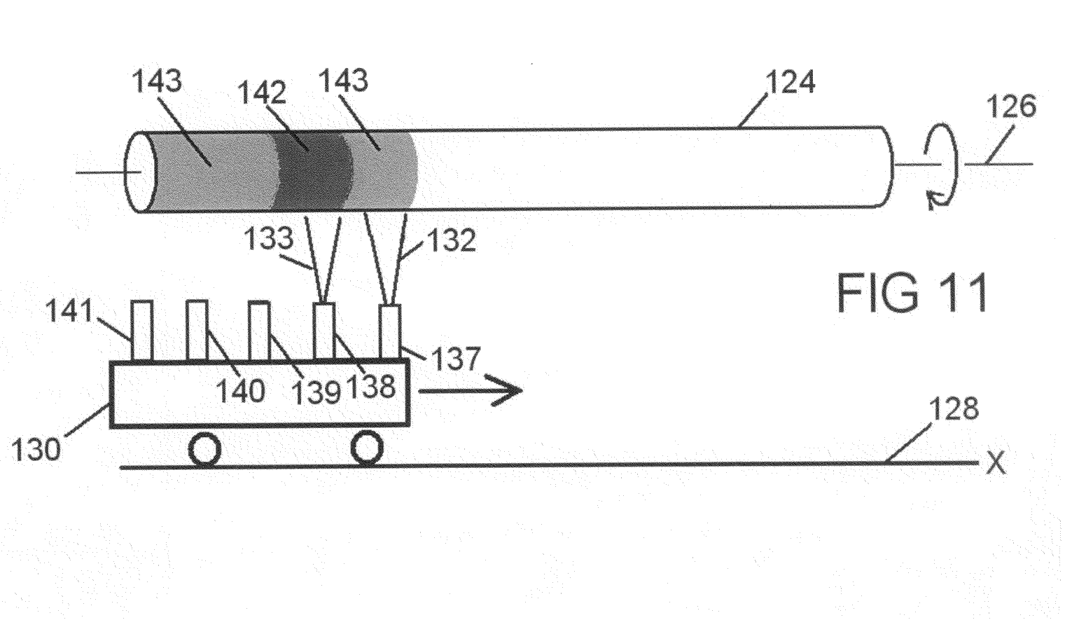

FIG. 11 depicts one possible manufacturing set-up for building a thermoelectric generator onto a round tube 124 by spraying annular rings of dielectric, conductor and thermoelectric material as appropriate. The tube 124 is rotated about axis 126. A carrier 130 with five controllable nozzles moves along the X axis 128 in the direction shown. It may move and then stop, or it may move continuously, with nozzles 137,138,139,140,141 individually controlled to either spray or to be turned off. To accomplish the coating depicted in FIG. 11, the nozzle for the first dielectric 137 is turned on as the carrier 130 moves from left to right. This results in a coating 143 of dielectric on the tube wall. Conductor spray 133 comes out of nozzle 138 and is applied over the dielectric coating 143 for a portion of the dielectric coated surface 143. As the carrier moves from left to right, nozzles for the conductor 138, second dielectric 139, N-type thermoelectric material 140 and P type thermoelectric material 141 are turned on or off as necessary to apply annular rings of material. When the carrier reaches the end of the tube, it reverses direction and sprays conductor and dielectric as needed on the return to the initial position in order to complete the application of the completed thermoelectric generator onto the tube wall. When the carrier 130 returns to its initial position, a new tube may be set-up for spray coating. In this way, the production technique is simple, can be automated and allows volume production.

Although FIG. 11 depicts a single nozzle 140 for spraying N-type thermoelectric material and a single nozzle 141 for spraying P-type material, in some circumstances it might be desirable to spray two or more layers of different N-type and two or more layers of different P-type material in order to produce graded thermoelements. Graded thermoelements have material characteristics that are matched to the anticipated temperature ranges that a given portion of the thermoelement is likely to be subjected to during operation. As such, the set-up in FIG. 11 might require additional nozzles to allow the application of graded thermoelements.

Although FIG. 11 depicts five distinct nozzles 137,138,139,140,141, it may be possible to use a single nozzle, with that single nozzle used to spray different materials during multiple passes.

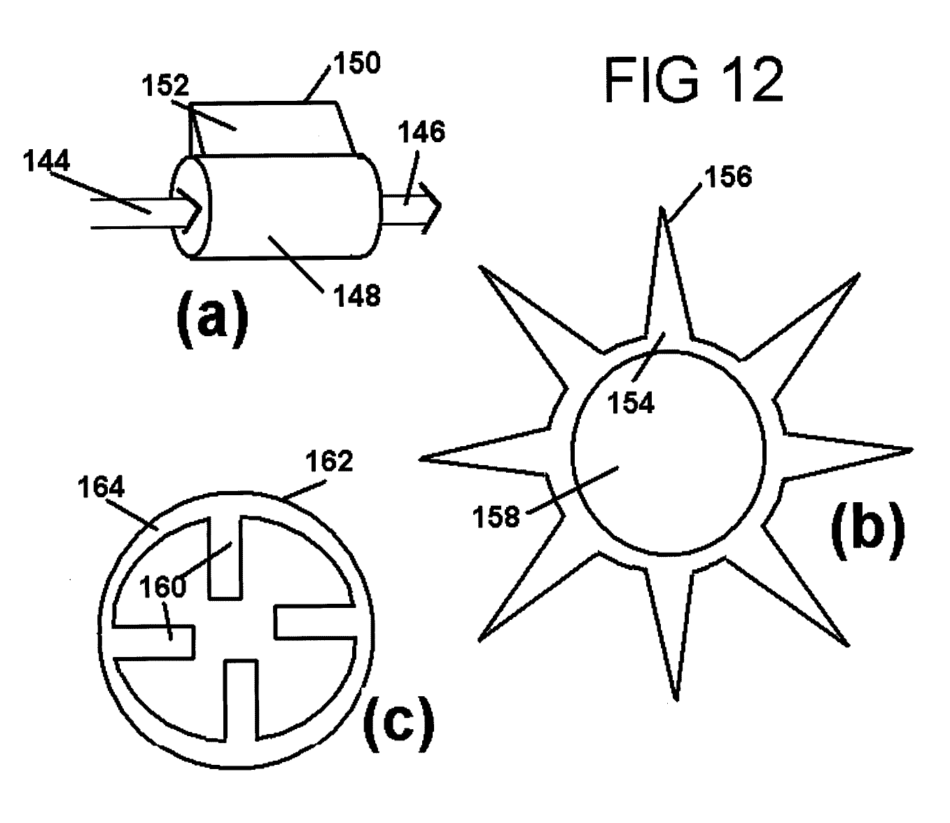

FIG. 12 (a) depicts a heat exchanger with a radiator fin. In this depiction, the heat exchanger consists of a tube 148 into which a fluid 144 flows, causing heat transfer to the tube 148. Fin 150 has a good mechanical and thermal attachment to tube 148 and serves to increase the net surface area of heat transfer to the medium in which tube 148 is placed. For example, the fluid 144 could be a water-antifreeze mixture and the medium into which tube 148 is placed could be air. This is the situation in a car radiator. The fluid 144 is cooled by passage through tube 148 due to the transfer of heat to the tube walls and from there to the fin 150. FIG. 12(b) depicts a cross sectional view of a tube with eight attached fins. Fluid flows through the fluid channel 158 (into the page) and transfers heat to the fins. In some embodiments, the base of each fin 154 will be wider than the tip 156. This tapered profile is advantageous in that it provides mechanical strength and a relatively low thermal resistance at the base 154 where it is more important relative to the tip 156. Tapering is advantageous in that it results in reduced material costs to achieve substantially the same cooling ability.

FIG. 12(c) depicts the cross-section of alternative arrangement in which internal fins 160 are oriented within the tube in order to enhance heat transfer from the internal fluid to the outside wall 162 of the tube 164.

Although the embodiments in FIG. 12 depict circular tubing, the cross-sectional tube shape may be oval, rectangular or have an arbitrary shape. The key feature that makes something a tube is that it have a hollow channel into which fluid may be conveyed. Some embodiments might have radiative fins both external (like FIG. 12(b)) and internal (like FIG. 12(c). In some embodiments, the fins will be nontapered and oriented in a parallel orientation in order to benefit from the so-called “chimney effect” wherein free convection causes a fluid motion across the fins, enhancing heat transfer away from the fin. In some embodiments, rather than a fluid, radiative fins may be used to transport heat away from a solid. An example of this is a so-called power resistor, which is an electrical component that is used for heaters or for dissipating electrical power.

In all of the examples of radiator fins given above, the fin surface is a good candidate for placing a thin thermoelectric generator because there is a significant temperature difference between the interior of the fin and the surface of the fin.

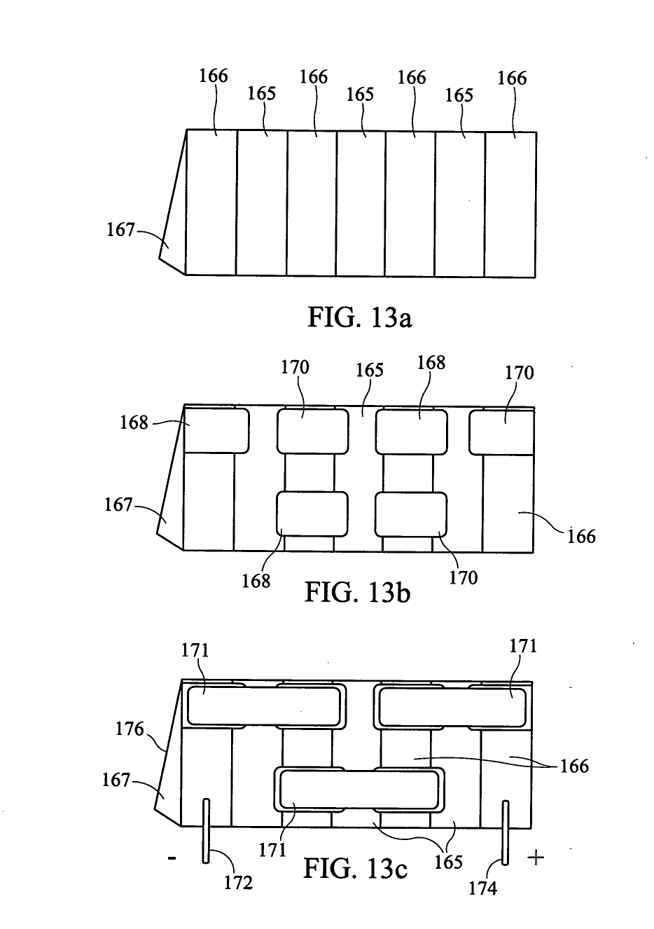

FIG. 13 depicts the coating process with which coatings may be applied to a flat surface, like a radiator fin, so as to produce a thermoelectric generator. A fin 167 has a configuration similar to that of fin 150 in FIG. 12. The fin surface 165 is first uniformly coated with a dielectric (electrical insulator) layer. This can be done, for example, by applying an oxide coating to the fin. In one approach, anodizing can be used whereby a thin layer of oxide is created over a metal surface. For example, if the fin 167 is made from aluminum, then an aluminum oxide coating may be effected through an electro chemical treatment. Aluminum oxide is a good electrical insulator. When it is applied in a very thin layer, it can provide good dielectric strength while still allowing good thermal transport from the interior of the fin 167 to the outside. A conductive coating 166 is applied in strips over the fin surface 165. This coating might be nickel or another good electrical conductor and the application means could be by a thermal spray process.

FIG. 13(b) depicts the location of the coating of n type thermoelectric material 168 and p type thermoelectric material 170. These could be applied, for example, by a spray coating technique. The coating 168 may be of a single n type thermoelectric material or it may consist of layers of two or more chemically distinct n type thermoelectric materials in order to accomplish a graded thermoelement that has desirable characteristics over the anticipated operational temperature ranges. In a similar way, the coating 170 may be of a single p type thermoelectric material or layers of two or more p type materials.

FIG. 13(c) depicts the application of a top conductor layer 171 to complete the thermoelectric circuit. There are three strips of the top conductor layer 171 that serve to make the series electrical connection to the six (three n type and three p type) thermoelements. Electrical terminals 172 and 174 are the means by which electrical energy is extracted from the thermoelectric generator. In the configuration shown, when the interior of the fin 167 is hotter than the external ambient, then heat flows from the fin 167 and electrical terminal 172 has a negative voltage potential relative to electrical terminal 174.

Although only one side of the fin 167 is depicted as being coated in FIG. 13, the other side 176 might also be coated to build a thermoelectric generator, allowing for a doubling of the thermoelectric generation capability. By connecting a number of such thermoelectric generators in electrical series, a step-up in voltage can be achieved. By connecting a number of such thermoelectric generators in electrical parallel, a step-up in current can be achieved.

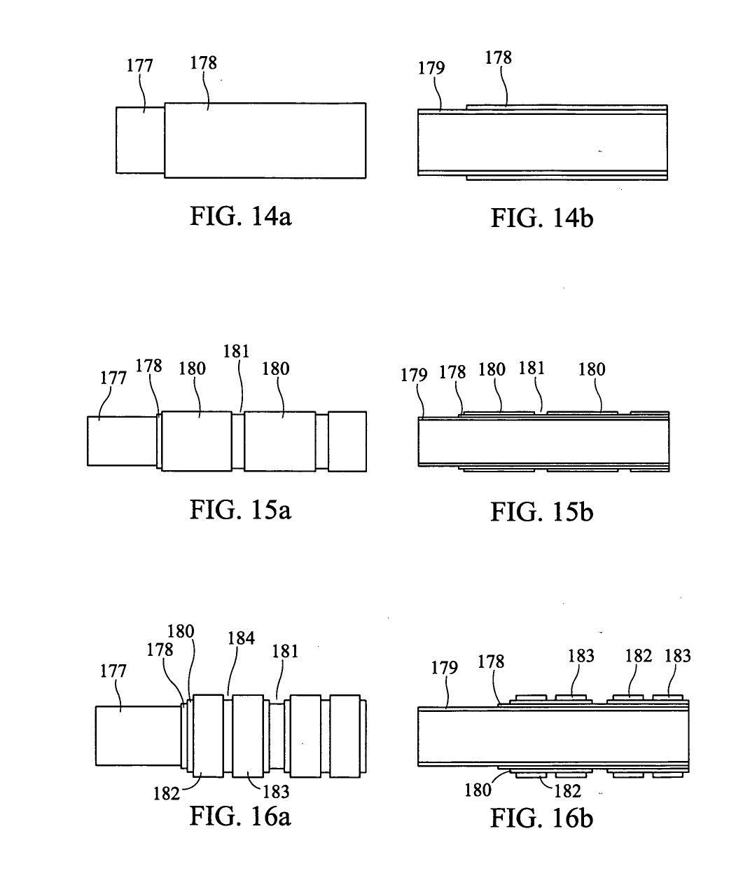

FIG. 14 shows the first step in which a thermoelectric generator may be built onto a circular tube 177. Tubes used in heat exchange applications are used as fluid conduits. They will almost always be built of a metal such as aluminum, copper or stainless steel. This is done because metals are good thermal conductors, a desirable feature for a heat exchanger. Because metals also happen to be good electrical conductors, it is necessary to start with a dielectric coating to prevent the metal tube from electrically short circuiting the applied thermoelectric generation components. Because the level of voltage generation that can occur from a thermoelectric couple is quite low, the dielectric breakdown requirements are quite modest and the dielectric coating can be designed to be quite thin, thereby providing isolation from the metal tube without compromising heat transfer out of the wall of the tube. That is, with a sufficiently thin dielectric layer, the additional thermal resistance added to the wall of the tube will be minimal. The dielectric layer can be added by applying a coating to the tube or by treating the outside of the tube so as to chemically change the tube surface to have a desired insulating property. One class of electrochemical treatments is known as anodization, whereby an oxide layer is deliberately added to the metal surface. FIG. 14(a) shows the outside of a metal tube 177 coated with (or treated to have) a dielectric layer 178. FIG. 14(b) shows a cutaway of the tube 177, showing the tube wall 179 and the dielectric layer 178. It should be noted that FIG. 14 is not drawn to scale. In an actual implementation, the dielectric layer 178 would be much thinner than the tube wall 179.

FIG. 15 depicts a circular tube 177 with annular rings of conductor 180 applied over the dielectric coating 178. The annular rings of conductor 180 completely surround the tube, that is, they are contiguous and are electrically separated from each other by a physical gap 181. FIG. 15(a) depicts the outside of the tube 177. FIG. 15(b) depicts a cut-away view.

FIG. 16 depicts the tube of FIG. 15 with additional coatings of P-type thermoelectric material 182 and N-type thermoelectric material 183 applied as annular rings. A gap 184 between the P-type thermoelectric coating 182 and the N-type thermoelectric coating prevents electrical short circuiting between the two rings. It should be noted that the spacings between various rings are not drawn to scale and, in most cases, gaps 181 between conductors and gaps 184 between rings of thermoelectric material can be very small and still provide sufficient dielectric isolation.

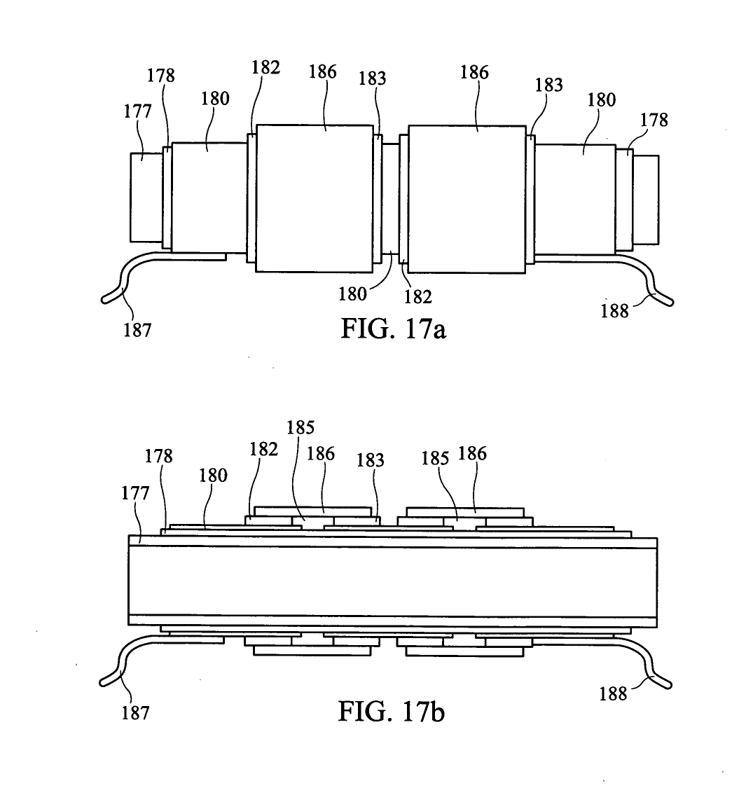

FIG. 17 depicts a tube onto which a complete, two-couple generator has been applied. FIG. 17 (a) shows the outside of the device and FIG. 17(b) shows a cut-away. The complete, two couple generator is built from the implementation depicted in FIG. 16 by adding two additional annular layers. A dielectric layer 185 is applied to fill in the gap between the P-type layer 182 and the N-type layer 183. Finally, a conductor layer 186 is applied to complete the electrical connection between P-type layer 182 and N-type layer 183. Power may be extracted from this generator through terminals 187 and 188, which are affixed to the exposed conductor layers 180 on either end of the tube. The generator in FIG. 17 is complete and can generate power when the inside of the tube is made to have a different temperature from the outside of the tube. In some applications, it may be desirable to add additional coatings over the outside of the tube to protect the thermoelectric generation layers from mechanical or chemical damage.

The tubular thermoelectric generator depicted in FIG. 17 is robust to damage because of the distributed nature of the annular design. Cracks or scratches in the series connection of conductors and thermoelements are accommodated by the electrical current simply taking a different path. It requires a complete circumferential breach in the tube coating to interrupt current flow.

Although the FIG. 17 implementation depicts a four thermoelement generator, the technique extends to an arbitrary number of thermoelements. It would be possible to use the technique to produce a tubular generator with fewer thermoelements than depicted in FIG. 17, and in the limit, produce a tubular generator with a single P-type thermoelement or a single N-type thermoelement. However, since the generated voltage from a single element is small, it is preferable to make a series connection of many elements in order to have higher voltages. Higher voltages have two advantages. First, the conversion electronics that are required to step up the voltages from the thermoelectric generator into relatively high output voltages, are generally more efficient for higher input voltage values. Second, for a given physical construction, and a given power output, higher electrical voltages implies lower electrical currents and hence less loss due to Joule heating within the conductors and thermoelements and less loss at contact drops. For example, over the temperature range of 0 to 100 degrees C., alloys of bismuth telluride have a average Seebeck coefficient of approximately 180 microvolt per degree C. So, for a 100 degree C. temperature difference, the generated voltage from a single thermoelectric cell would be (100 C)(180 μV/C) for a generated voltage of 18 millivolts. In order to produce 180 watts of power from that single cell thermoelectric generator, it would be necessary to size it to produce 10,000 amperes of electrical current. In contrast, by using 100 thermoelectric elements in electrical series, it would be possible to generate 1.8 volts and would require a current of only 100 amperes. Since losses in the power conditioning circuitry are proportional to the square of the electrical current, having more cells is generally a more efficient way to produce electrical power.

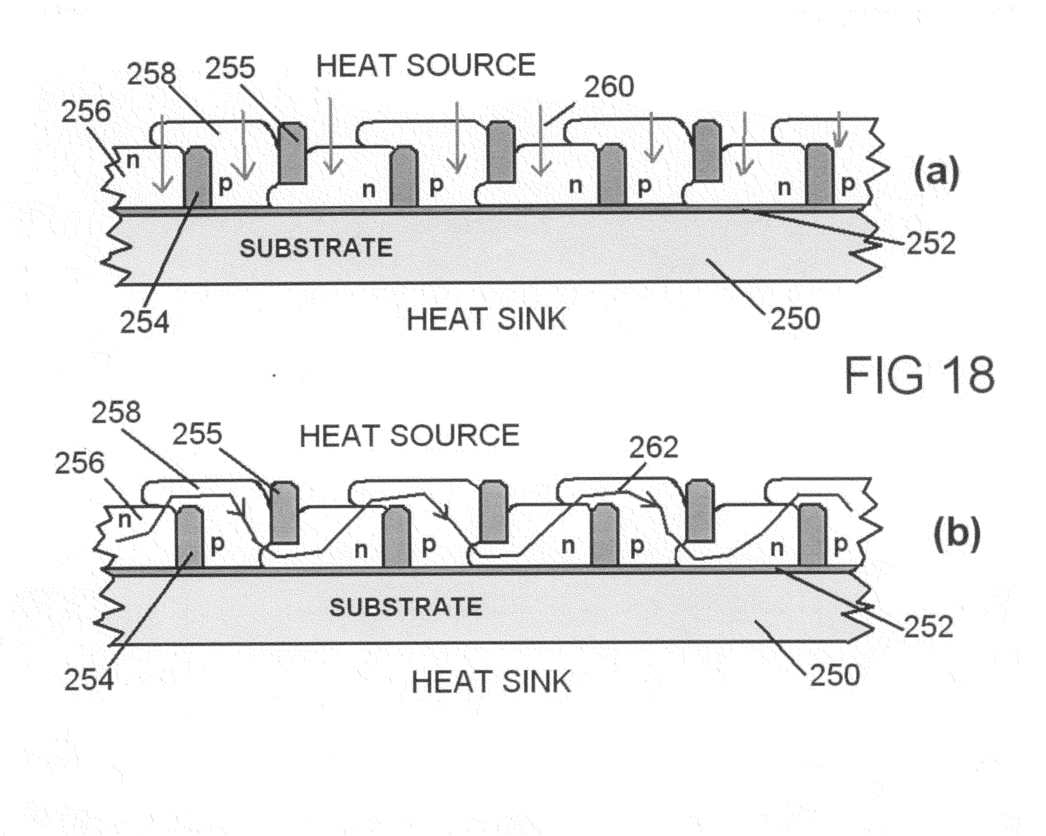

FIG. 18(a) depicts the cross section of a way in which thermoelectric materials may be applied to a substrate 250 to produce a thermoelectric device without requiring the use of a separate electrical conductive layer. The substrate 250 may be a flat substrate such as a radiator fin or it might be a tubular element. If the substrate 250 is an electrical conductor, it must have a dielectric coating 252 that prevents the short circuiting of the thermoelectric elements by the substrate 250. The dielectric coating 252 is an electrical insulator and might be, for example, an anodization layer. N type thermoelectric material 256 and lower insulator material 254 is first applied to the dielectric coating 252. This is followed by an application of upper insulator material 255 and then p type thermoelectric material 258. In FIG. 16(a) the heat source is depicted on the top of the structure and the heat sink is depicted on the bottom of the structure. The heat flow 260 is from hot to cold and passes through the thermoelectric elements 256 and 258.

FIG. 18(b) depicts the electrical current 262 that is generated in response to the temperature gradient across the thermoelements 256 and 258. The n type thermoelements 256 and the p type thermoelements 258, are themselves electrical conductors, so there is not a need to use a separate electrically conductive coating.

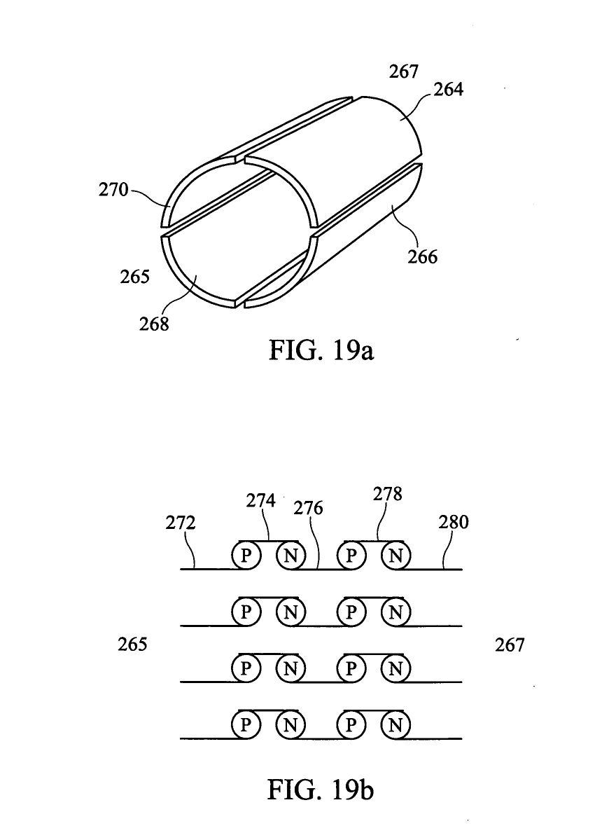

FIG. 19 (a) depicts a tube to which a thermoelectric generator has been applied to the tube wall and which has been cut into four longitudinal sections. The orientation shown in FIG. 19 depicts one end of the tube, the proximal end 265, as being closer than the other, distal end of the tube 267. Because the coatings that make the thermoelectric generation feature are applied in structures that completely surround the tube, when the tube is cut as shown, the result is four identical, functioning thermoelectric generation devices. If the original, precut thermoelectric tube generator was designed to have two couples, then each of the four sections of the cut tube will have two couples. FIG. 19(b) depicts the electrical schematic corresponding to the four sections. Each section can be represented by an identical electrical schematic. Electrical terminal 272 is defined to be the conductor nearest to the proximal end of one of the longitudinal sections 264 of the quartered tube. Electrical terminal 272 makes an electrical connection to a P-type thermoelement. A conductor 274 connects the P-type thermoelement to an N-type thermoelement. A conductor 276 connects the N-type thermoelement to a second P-type element. A conductor 278 connects the second P-type element to a second N-type element. Finally, the second N-type thermoelement is connected to an electrical terminal 280 which is the conductor on section 264 nearest the distal end of the quartered tube. Each of the other longitudinal sections of the tube can be represented by an identical electrical schematic.

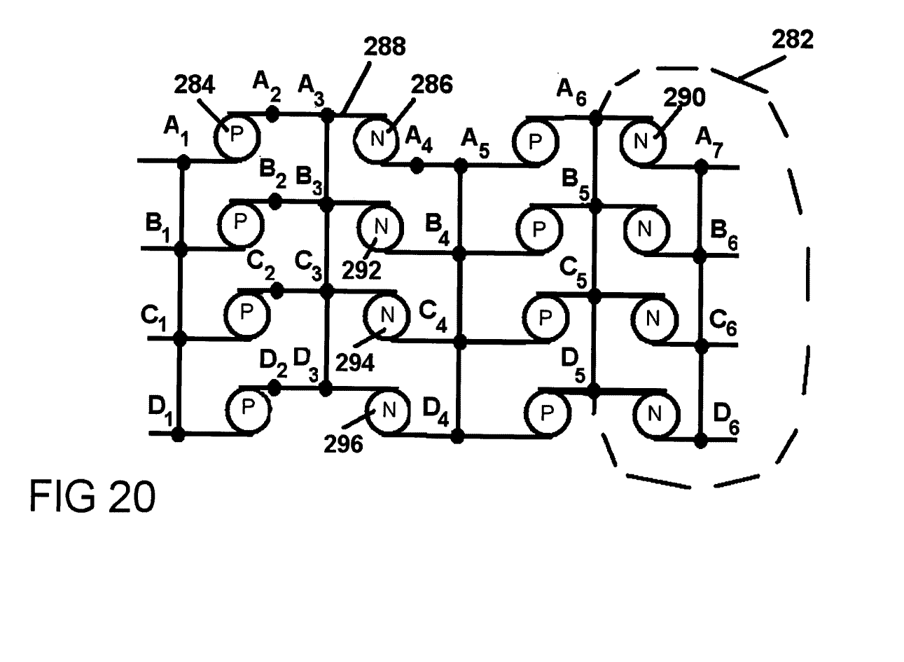

FIG. 20 depicts an electrical schematic for the original (unsectioned) thermoelectric generator coated tube that assumes a lumped model for the thermoelectric circuit corresponding to the thermoelectric generation tube divided into four longitudinal parts. Because coatings extend continuously in a circumferential manner around the tube, node A₆ has a direct connection 282 to node D₅ without going through nodes B₅ and C₅. In a similar way, node A₁ has a direct electrical connection to node D₁ without going through nodes B₁ and C₁, and node A₅ has a direct electrical connection to node D₄ without going through nodes B₄ and C₄. The interconnected nature of this system allows robustness to broken electrical connections because if a break occurs, electrical current can take alternative paths. For example, consider an open circuit condition occurring between nodes A₂ and A₃. This might happen, for example if the thermoelectric generator experienced a cut in the outermost conductor 288, over the region connecting P-type thermoelement 284 to N-type thermoelement 286. It might also occur if the attachment between P-type thermoelement 284 and conductor 288 was lost due to mechanical defect or bond breakage occurring due to the stress of thermal cycling. If the open circuit condition occurs between points A₂ and A₃, the result is that the single P-type thermoelement 284 is removed from the electrical circuit and does not contribute to thermoelectric generation. In a similar way, an open circuit condition between nodes A₄ and A₅ will cause the loss of a single N-type thermoelement 286.

An open circuit condition between nodes A₆ and B₅ has no impact on the performance of the thermoelectric generator because each part of the thermoelectric generator that corresponds to a fictitious longitudinal partition can function independently and so the electrical current flowing into node A₇ from N-type thermoelement 290 will be unchanged.

As noted from the above discussion, the thermoelectric generator of the present invention is robust to open circuit conditions. The only way that generator function will be completely interrupted due to open circuit conditions is if damage occurs circumferentially so as to completely sever an electrical conductor. This condition corresponds to an electrical open circuit between all of node pairs (A₂,A₃), (B₂,B₃), (C₂,C₃) and (D₂,D₃).

Besides open circuit conditions, another broad class of damage is electrical short circuits where low resistance electrical connections are made between electrical conductors. In FIG. 20, an electrical short circuit between nodes A₃ and A₄ will serve to bridge N-thermoelement 286, effectively removing its generation capability from the circuit. Since node A₃ is electrically connected to nodes B₃, C₃ and D₃, and node A₄ is electrically connected to nodes B₄, C₄ and D₄, N-thermoelements 292, 294 and 296 will also be short circuited. The result will be that this particular system will have a 25% reduction in generation capability since it has lost 25% of its lumped thermoelements.

The FIG. 19(b) and FIG. 20 electrical schematics are lumped models of a distributed system. The choice of four longitudinal sections was arbitrary and made to illustrate the interconnectedness that is obtained by using coatings and the robustness with which a distributed design can tolerate damage. A more accurate model would use a larger number, J, of partitions, corresponding to J parallel two-couple thermoelectric devices, all highly interconnected. The design tolerates open electrical conditions quite well. Such open circuit conditions can arise from scratches, dents, cuts or other externally applied mechanical damage, as well as breaks and loss of connection that can occur internally due to manufacturing defect or stresses due to thermal cycling. For the most part, these types of damage will not affect performance unless the damage is extensive, for example, in the case of a circumferential cut in the topside conductor. Electrical short circuits are more significant and will serve to completely remove one of the thermoelements in a design. For the two-couple system depicted in FIG. 17, this results in a 25% reduction in generation capability. A system with a larger number of series connected thermoelements will be less sensitive to the loss of any one thermoelement due to an electrical short circuit.

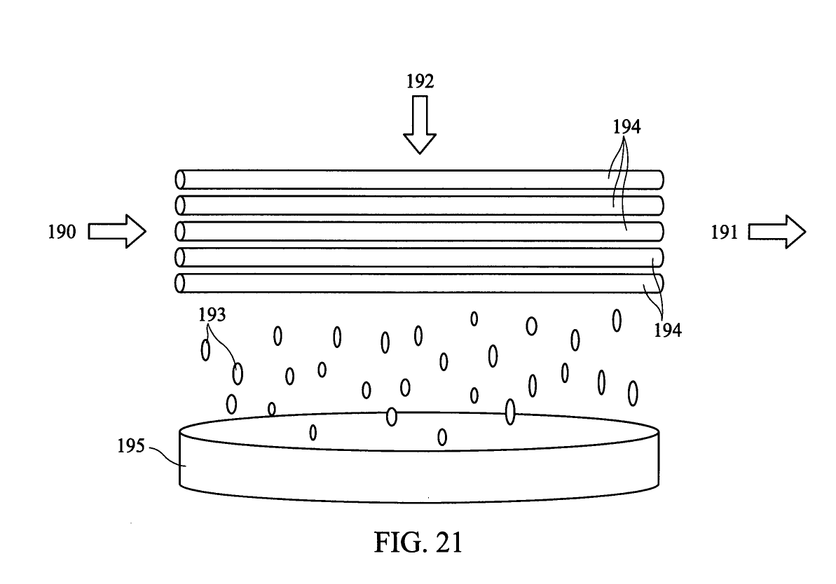

FIG. 21 depicts the tubular thermoelectric generator as used in a condenser application. Condensers are heat exchangers that are used to effect a phase change by cooling a gas to make it a liquid. In one common type of condenser that is used in a power plant, liquid water running through tubes is used for the heat sink and water vapor (steam) is passed over the tubes and serves as the heat source. When thermal energy is transferred from the steam to the tubes, it causes a phase change and the steam is converted to liquid water. Tubular thermoelectric generators 194 are the conduit for the liquid water. These consist of parallel disposed tubes, the surface of which has been prepared to have attached thermoelectric generation devices. The generators 194 may be connected in electrical series or electrical parallel (not shown) to transport generated electrical energy away from the generator and to an electrical load or an electrical network. Cold water 190 enters the tubes on the left and as heat is transferred to the water, exits the tubes as warmer water 191 on the right. In FIG. 21, steam 192 is depicted as coming in from the top. As the steam condenses into liquid water, it falls as droplets 193 to be captured in a catchbasin 195. In a steam generation plant, the water from catchbasin 195 is then routed to a boiler for the production of steam in a closed cycle. The use of thermoelectric generation in a condenser is a means of capturing useful electrical power as a byproduct of the condensing task.

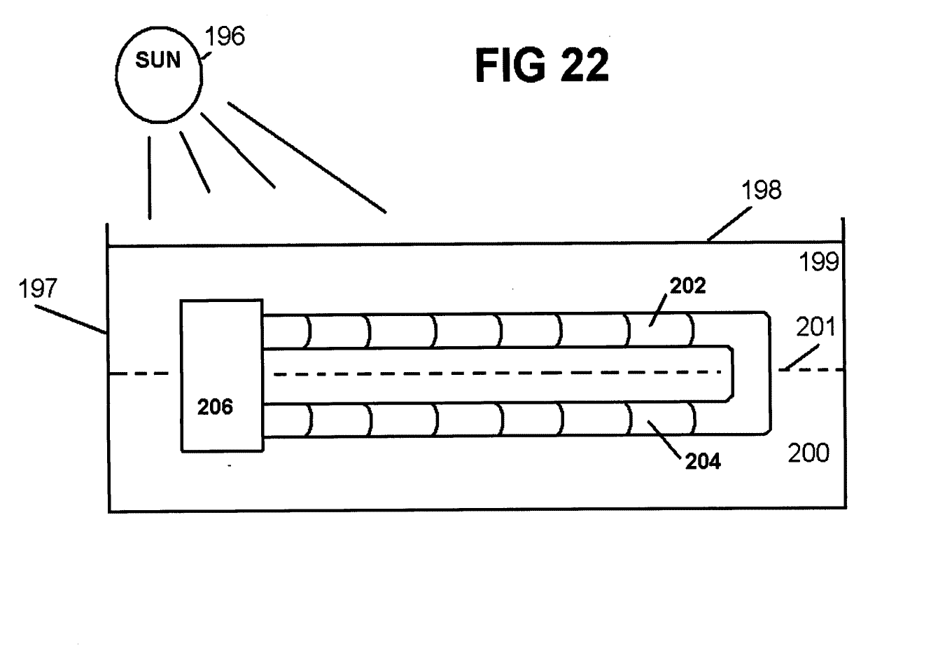

FIG. 22 depicts the tubular thermoelectric generator as used in a solar pond 197. Solar pond 197 is a body of water that contains layers of salt solutions. The top layer 199 has low salt content, the bottom layer 200 has high salt content and the intermediate layer has an intermediate salt content and establishes a density gradient that prevents heat exchange by natural convection. The solar pond operates to store solar energy. The sun 196 radiates to the surface 198 of the solar pond. Solar radiation penetrates to the lower layer 200 and is blocked from reradiating out by the upper layer 199. A boundary 201 may be used to indicate the interface between layers, although this is somewhat artificial since there is a continuum between the layers. The difference in temperature between the top 199 and bottom 200 layers may be on the order of 60 or more degrees Celsius. A potential problem with harvesting the heat energy in a solar pond is that if heated water from the bottom layer 200 is pumped out of the solar pond, this serves to agitate the pond, causing an undesirable intermixing of the top 199 and bottom 200 layers. The configuration in FIG. 22 presents an alternative that does not result in the intermixing of layers. A tubular thermoelectric generator 202 is positioned in the top layer 199 and a tubular thermoelectric generator 204 is positioned in the bottom layer 200 of the solar pond. A pump 206 serves to move a working fluid in a circular movement from thermoelectric generator 204 to thermoelectric generator 202 and back to thermoelectric generator 204. The working fluid is in a closed system and will not intermix with the liquid in the solar pond. The process might optimally be done in a timed pulsing. For example, turn the pump off for ten minutes, allowing electric generation from both thermoelectric generators for ten minutes as heat moves from outside to the inside of generator 204 and heat moves from the inside to the outside of generator 202. As the fluid inside generators 202 and 204 attains a temperature approaching the outside temperatures (of layers 199 and 200 respectively), then electric generation would taper off and this would signal the pump to turn on for a brief time period in order to exchange the contents of the upper generator 202 for the contents of the lower generator 204. The power requirements to drive the pump would be minimal because the system would be closed cycle and the power required to lift the working fluid the short distance between layers would be minor. Furthermore, the duty cycle might be on the order of 2%, for example, on for ten seconds, off for ten minutes. In different permutations of this application of thin walled tubular thermoelectric generators, the thermoelectric generator might only be in one layer. In some permutations, a single thermoelectric generator might be in the lower liquid level 200 but would be pumped outside the pond to an external heat exchanger. In this type of application, the working fluid inside the thermoelectric generator might be pumped continuously.

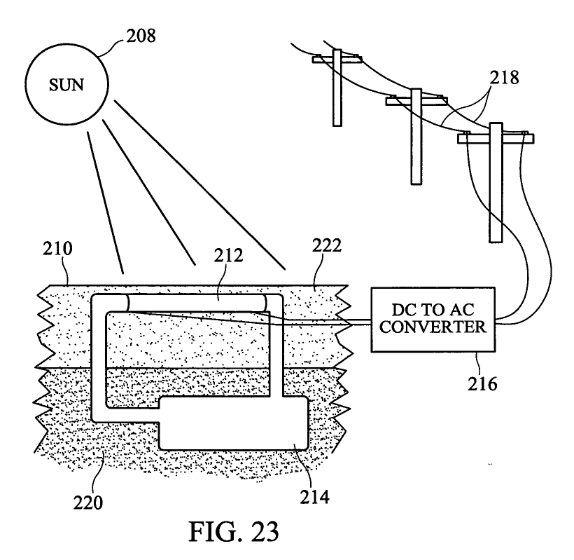

FIG. 23 depicts the tubular thermoelectric generator as used to harvest solar energy from a roadway. A square meter of roadway receives the same incident solar radiation as a square meter of photovoltaic panel (solar cell array). By using a thermoelectric generator embedded within a roadway, it is possible to indirectly capture some solar energy from the heat in the roadway. The sun 208 shines onto the pavement surface 210, heating it up. The upper portion of the pavement 222, which is near the surface, gets warmer than subsurface layers. A subsurface reservoir 214 that is located a substantial distance under the roadway is in a location with relatively constant temperature. By pumping a working fluid through the thermoelectric generator (pump not shown), it is possible to generate electricity from the temperature difference between the upper pavement 222 into which the thermoelectric generator is embedded, and the temperature of the fluid held in the reservoir 214. During periods when the upper pavement is cooler than the reservoir temperature, electric generation may still be carried out but with the opposite polarity. The DC voltage generated from the thermoelectric generator is transformed into an AC voltage suitable for delivery to the electrical grid 218 by a DC to AC converter 216. Alternatively, the power could be used locally, for example to power roadway signage or lighting. Although the reservoir 214 is depicted as lying beneath the pavement 210, it might equally well be located to the side of the road, buried under earth or in an above surface storage. Instead of a voluminous reservoir, a length of subsurface pipe could be used. Finally, it should be noted that in this particular application, the thermal differential arises from a solid (the upper pavement layer 222) relative to a liquid (the working fluid pumped through the thermoelectric generator).

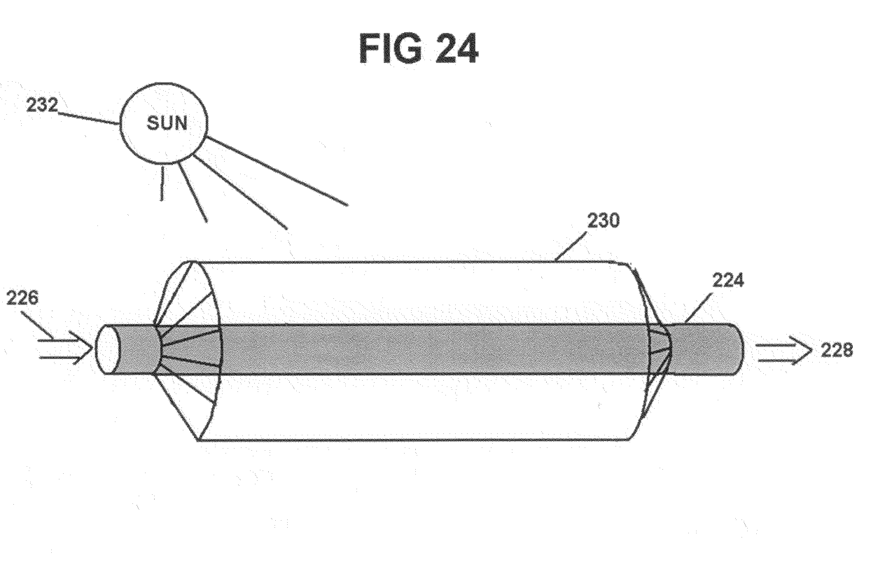

FIG. 24 depicts a tubular thermoelectric generator that is used together with a vacuum tube solar collector in order to produce electricity from solar energy. This type of design consists of an evacuated transparent tube 230 that allows solar radiation to enter, but has a coating that impedes radiative heat transfer back out. The tubular thermoelectric generator 224 has a high absorptive coating that allows it to absorb the majority of the received radiation. The fact that the tube 230 is evacuated means that there is little convective heat transfer away from the tubular thermoelectric generator 224. The path for heat is through the wall of the generator 224 to a fluid inside. A working fluid is passed through the tubular thermoelectric generator, entering from the left 226 and exiting from the right 228 in FIG. 24. This fluid is cool and might, for example, be obtained from a large reservoir that is relatively cool. The amount of solar energy that can be captured can be increased by applying a reflective coating to half of the evacuated tube 230 and then directing the tube 230 so that the clear half is oriented toward the sun. Alternatively, a parabolic solar trough can be positioned beneath the transparent tube 230 to capture solar energy. It should be noted that this application is unique from previous examples in that energy is imparted to the hot side of the thermoelectric generator via radiative means and not through contact to a solid or fluid heat transfer material.

Although the invention has been described in detail with particular references to these preferred embodiments, other embodiments can achieve the same results. Variations and modifications of the present invention will be obvious to those skilled in the art and it is intended to cover in the appended claims all such modifications and equivalents. The entire disclosure of all references, applications, patents, and publications cited above are hereby incorporated by reference.

What is claimed is:

1. A thermoelectric generator deployed on the wall of a heat exchanger, comprising:
a) dielectric coatings,
b) electrical conductor coatings,
c) N-type thermoelectric material coatings, and
d) P-type thermoelectric material coatings,
whereby electricity generation is obtained as a byproduct of heat exchange.

2. The thermoelectric generator of claim 1 wherein said dielectric coatings are applied using a spraycast technique.

3. The thermoelectric generator of claim 1 wherein said electrical conductor coatings are applied using a spraycast technique.

4. The thermoelectric generator of claim 1 wherein said N-type thermoelectric material coatings are applied using a spraycast technique.

5. The thermoelectric generator of claim 1 wherein said P-type thermoelectric material coatings are applied using a spraycast technique.

6. The thermoelectric generator of claim 1 wherein said heat exchanger is a tube.

7. The thermoelectric generator of claim 6 wherein said dielectric coatings are applied to said tube using a spraycast technique.

8. The thermoelectric generator of claim 6 wherein said electrical conductor coatings are applied to said tube using a spraycast technique.

9. The thermoelectric generator of claim 6 wherein said N-type thermoelectric material coatings are applied to said tube using a spraycast technique.

10. The thermoelectric generator of claim 6 wherein said P-type thermoelectric material coatings are applied to said tube using a spraycast technique.

11. The thermoelectric generator of claim 7 wherein said spraycast technique is applied to said tube while it is rotating, thereby resulting in the deposition of one or more annular rings of dielectric coating upon said tube.

12. The thermoelectric generator of claim 8 wherein said spraycast technique is applied to said tube while it is rotating, thereby resulting in the deposition of one or more annular rings of electrical conductor.

13. The thermoelectric generator of claim 9 wherein said spraycast technique is applied to said tube while it is rotating, thereby resulting in the deposition of one or more annular rings of N-type thermoelectric material.

14. The thermoelectric generator of claim 10 wherein said spraycast technique is applied to said tube while it is rotating, thereby resulting in the deposition of one or more annular rings of P-type thermoelectric material.

15. The thermoelectric generator of claim 1 wherein said dielectric coatings are applied by oxidizing the surface of a metal tube.

16. The thermoelectric generator of claim 1 wherein said wall comprises the fin on a heat sink.

17. The thermoelectric generator of claim 1 wherein said N-type and said P-type coatings are designed to have a thickness that is tailored for maximum power generation.

18. The thermoelectric generator of claim 6 wherein said coatings are applied in annular rings, resulting in a structure that is robust to damage.

19. The thermoelectric generator of claim 6 consisting of one or more complete thermoelectric couples, thereby allowing generator function in the case of structural damage.

20. A method of constructing a thermoelectric generator, comprising the application of coatings of dielectric, electrical conductor, N-type and P-type thermoelectric materials to the wall of a heat exchanger.

21. The method of claim 20 wherein said heat exchanger is a tube.

22. The method of claim 21 wherein said coatings are applied in rings.

23. The method of claim 20 wherein said coatings are applied using spraycasting.
